(19) United States
(12) Patent Application Publication
(10) Pub. No.: US 2025/0344429 A1
(43) Pub. Date: Nov. 6, 2025

(54) SEMICONDUCTOR DEVICE WITH METAL GATE STRUCTURE AND FABRICATION METHOD THEREOF

(71) Applicant: Taiwan Semiconductor Manufacturing Company, Ltd., Hsin-Chu (TW)

(72) Inventors: Cheng-I Lin, Hsinchu (TW); Shu-Han Chen, Hsinchu City (TW); Chi On Chui, Hsinchu City (TW)

(21) Appl. No.: 19/272,449

(22) Filed: Jul. 17, 2025

Related U.S. Application Data
(63) Continuation of application No. 18/488,659, filed on Oct. 17, 2023.
(60) Provisional application No. 63/511,319, filed on Jun. 30, 2023.

(51) Int. Cl. H10D 30/43; H10D 30/01; H10D 30/67; H10D 62/10; H10D 64/01

(52) U.S. Cl. CPC H10D 30/43; H10D 30/014; H10D 30/6729; H10D 30/6735; H10D 30/6739; H10D 62/121; H10D 64/01; H10D 64/017; H10D 64/018

(57) ABSTRACT

A semiconductor device includes a fin-shaped base protruding from a substrate, an isolation feature disposed on sidewalls of the fin-shaped base, nanostructures vertically stacked over the fin-shaped base, and a gate structure. The gate structure includes a gate dielectric layer wrapping around the nanostructures, a first gate electrode disposed on the gate dielectric layer, a second gate electrode disposed on the first gate electrode, and a dielectric spacer disposed on a sidewall of the second gate electrode. The semiconductor device further includes a gate spacer extending along a sidewall of the gate structure. A dielectric constant of the gate dielectric layer is greater than a dielectric constant of the gate spacer, and the dielectric constant of the gate dielectric layer is greater than a dielectric constant of the dielectric spacer.

### PRIORITY DATA

This is a continuation application of U.S. patent application Ser. No. 18/488,659, filed Oct. 17, 2023, which claims the benefits of U.S. Provisional Patent Application No. 63/511,319, filed Jun. 30, 2023, each of which is incorporated herein by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, it is important to reduce parasitic capacitance among conductive features of transistors, such as parasitic capacitance between a metal gate structure and a source/drain contact, in order to increase device switching speed, decrease switching power consumption, and/or decrease coupling noise of the transistors. Certain low-k materials having a dielectric constant less than about 5.0, such as a dielectric constant lower than that of silicon oxide (about 3.9), have been suggested as insulator materials for various dielectric layers outside of a gate structure, such as gate spacers and interlayer dielectric (ILD) layer, which may provide lower relative permittivity to reduce parasitic capacitance. However, as semiconductor technology progresses to smaller geometries, the distance between a metal gate structure and a source/drain contact is further reduced, and a relatively high dielectric constant of dielectric material(s) inside a gate structure (e.g., a high-k dielectric layer) becomes a factor causing large parasitic capacitance that should no longer be omitted. Therefore, although existing approaches in transistor formation have been generally adequate for their intended purposes, as transistor dimensions are continually scaled down to sub-10 nm technology nodes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method of forming a semiconductor device, according to various aspects of the present disclosure.

FIGS. 2, 3, 4, 5, 6, 7, 8, 9, 10, 11, 12, 13, 14, 15, and 16 illustrate perspective views of a semiconductor structure during fabrication stages of the method in FIG. 1, according to various aspects of the present disclosure.

FIGS. 17, 18, 19, 20, 21, 22, 23, 24, 25, 26, 27, 28, 29, and 30 illustrate cross-sectional views of a semiconductor structure during fabrication stages of the method in FIG. 1, according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure is generally related to a semiconductor device and methods of forming the same. More particularly, the present disclosure is related to providing methods and structures in semiconductor manufacturing for lowering parasitic capacitance between a gate structure and a source/drain contact of a field effect transistor (FET), such as a fin-like FET (FinFET) or a gate-all-around (GAA) transistor.

In the forming of FETs, it is important to increase device switching speed, decrease switching power consumption, and decrease coupling noise. Parasitic capacitance generally has a negative impact on these parameters, especially from parasitic capacitance between a gate structure and a source/drain contact. For example, in a ring oscillator circuit consisting of an odd number of inverter stages connected in a loop, parasitic capacitance can increase the effective load on each inverter stage within the ring oscillator. As a result, it takes longer for the output to propagate through each stage, reducing the circuit's speed.

Parasitic capacitance exists within a capacitor-like structure consisting of two conductive features with insulating material therebetween. Dielectric constant, which is a measure of an insulating material's ability to store electrical energy in the form of an electric field, of the insulating material directly impacts the parasitic capacitance of the structure. In an FET, the gate electrode inside a metal gate structure and an adjacent source/drain contact, which are two conductive features, with the insulating material (generally a multi-layer structure including interlayer dielectric (ILD) layer, gate spacers, and a gate dielectric layer) therebetween form such a structure. Certain low-k materials, with a dielectric constant lower than that of silicon oxide, have been suggested as insulator materials for various dielectric layers outside of a gate structure, such as gate spacers and/or the ILD layer, which may provide a lower dielectric constant to reduce parasitic capacitance. As semiconductor technology progresses to smaller geometries, the distance between a gate electrode inside a metal gate structure and source/drain contacts shrink, and the portion of the gate dielectric layer in the multi-layer insulating material increases, such that the high dielectric constant of a gate dielectric layer cannot be ignored in estimating parasitic capacitance. Generally, a gate dielectric layer includes high dielectric constant (high-k) material(s) for better electrostatic control of the channel and suppression of leakage current when an FET is in an OFF-state. However, the high-k material(s) in the gate dielectric layer leads to a larger parasitic capacitance.

Consequently, with transistor dimensions are continually scaled down to sub-10 nm technology nodes and below, parasitic capacitance in FETs has become more problematic. The present disclosure aims at providing solutions in further reducing the effective dielectric constant of the insulating material interposing a gate structure and a source/drain contact, in an effort of lowering parasitic capacitance.

Some exemplary embodiments of the present disclosure are related to, but not otherwise limited to, multi-gate devices. Multi-gate devices have been introduced in an effort to improve gate control by increasing gate-channel coupling, reduce OFF-state current, and reduce short-channel effects (SCEs). One such multi-gate device that has been introduced is the fin-like field-effect transistor (FinFET). The FinFET gets its name from the fin-like structure which extends from a substrate on which it is formed, and which is used to form the FET channel. Another multi-gate device, introduced in part to address performance challenges associated with the FinFET, is the gate-all-around (GAA) transistor. The GAA transistor gets its name from the gate structure which can extend around the channel region (e.g., a stack of nanosheets) providing access to the channel on four sides. The GAA transistor is compatible with conventional complementary metal-oxide-semiconductor (CMOS) processes and its structure allows it to be aggressively scaled while maintaining gate control and mitigating SCEs. The following disclosure will continue with one or more GAA examples to illustrate various embodiments of the present disclosure. It is understood, however, that the application should not be limited to a particular type of device, except as specifically claimed. For example, aspects of the present disclosure may also apply to implementation based on FinFETs or planar FETs.

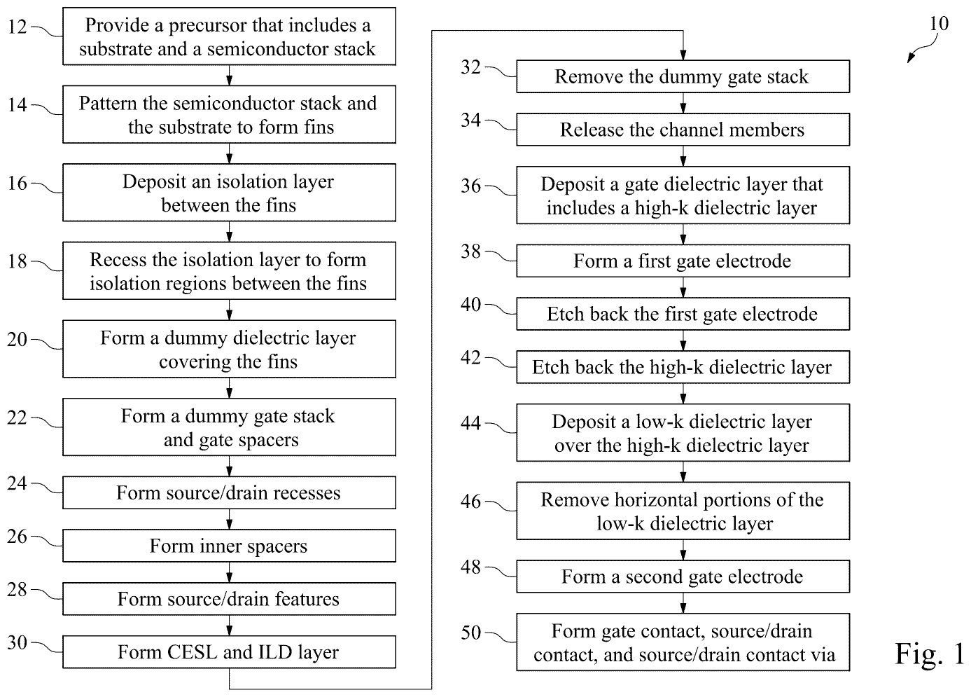

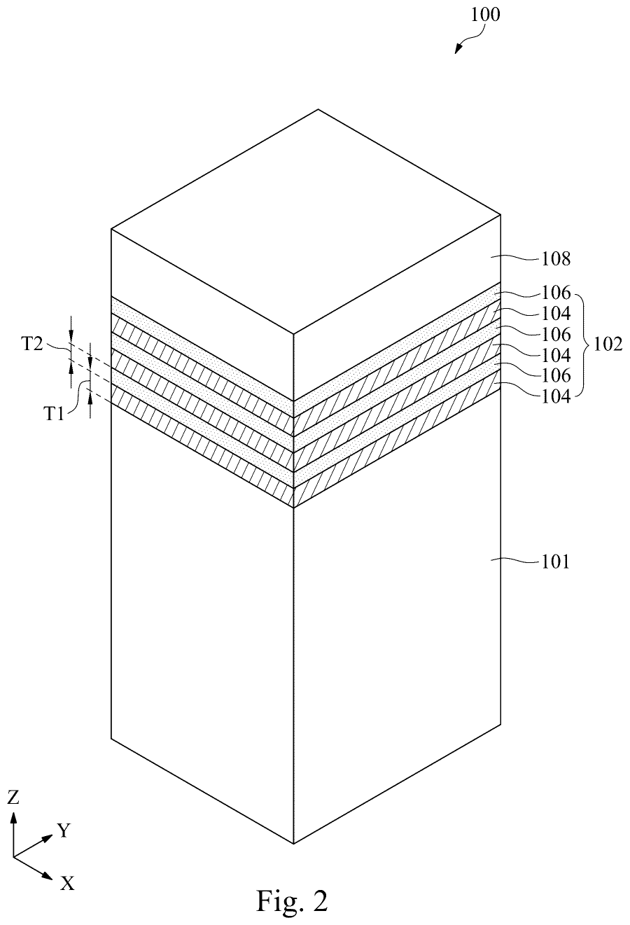

FIG. 1 illustrates a flow chart of a method 10 for forming a semiconductor device according to the present disclosure. The method 10 is an example, and is not intended to limit the present disclosure beyond what is explicitly recited in the claims. Additional operations can be provided before, during, and after the method 10, and some operations described can be replaced, eliminated, or relocated for additional embodiments of the method. The method 10 is described below in conjunction with FIGS. 2-30, which illustrate perspective views and cross-sectional views of a semiconductor device 100 during various fabrication steps according to some embodiments of the method 10. The semiconductor device 100 may be an intermediate device fabricated during processing of an integrated circuit (IC), or a portion thereof, that may comprise static random access memory (SRAM) and/or logic circuits, passive components such as resistors, capacitors, and inductors, and active components such as p-type FETs (pFETs), n-type FETs (nFETs), metal-oxide semiconductor field effect transistors (MOSFET), and complementary metal-oxide semiconductor (CMOS) transistors, bipolar transistors, high voltage transistors, high frequency transistors, other memory cells, and combinations thereof. Furthermore, the various features including transistors, gate stacks, active regions, isolation structures, and other features in various embodiments of the present disclosure are provided for simplification and ease of understanding and do not necessarily limit the embodiments to any types of devices, any number of devices, any number of regions, or any configuration of structures or regions.

Referring to FIGS. 1 and 2, at operation 12, the method 10 (FIG. 1) provides (or receives) a precursor of the semiconductor device 100. For the convenience of discussion, the precursor of the semiconductor device 100 is also referred to as the device 100. The device 100 may include a substrate 101 and various features formed therein or thereon. In some embodiments, the substrate 101 includes a crystalline silicon substrate (e.g., wafer). The substrate 101 may include various doped regions (e.g., p-type well and/or n-type well) depending on design requirements. In some embodiments, the doped regions may be doped with p-type or n-type dopants. For example, the doped regions may be doped with p-type dopants, such as boron or BF₂, n-type dopants, such as phosphorus or arsenic, and/or combinations thereof. The doped regions may be configured for n-type transistors, or alternatively, configured for p-type transistors. In some embodiments, an anti-punch-through (APT) implantation is performed on a top portion of the substrate 101 to form an APT region. The conductivity type of the dopants implanted in the APT region is the same as that of the doped regions (or wells). The APT region may extend under the subsequently formed source/drain regions, and are used to reduce the leakage from the source/drain regions to substrate 101. Source/drain region(s) may refer to a source or a drain, individually or collectively dependent upon the context. For clarity, the doped regions and the APT region are not illustrated in FIG. 1 and subsequent drawings. In some alternative embodiments, the substrate 101 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or combinations thereof.

The device 100 includes a semiconductor stack 102 formed on the substrate 101. The semiconductor stack 102 may include a plurality of first layers 104 and a plurality of second layers 106 stacked alternately in a Z-direction. Although only three first layers 104 and three second layers 106 are illustrated in FIG. 2, the embodiments of the present disclosure are not limited thereto. In other embodiments, the number of the first layers 104 and the second layers 106 are adjusted by the need, such as one, two, four, or more first layers 104 and second layers 106.

In some embodiments, the first layers 104 and the second layers 106 include different materials. For example, the first layers 104 are SiGe layers having a germanium atomic percentage in the range between about 15% and 40%, and the second layers 106 are Si layers free from germanium. However, the embodiment of the disclosure is not limited thereto, in other embodiments, the first layers 104 and the second layers 106 have materials with different etching selectivity. In some embodiments, the first layers 104 and the second layers 106 are formed by an epitaxial growth process, such as a molecular beam epitaxy (MBE) process, a metalorganic chemical vapor deposition (MOCVD) process, or the like. In the case, the first layers 104 are epitaxial SiGe layers, and the second layers 106 are epitaxial Si layers. In some alternative embodiments, the first layers 104 and the second layers 106 are formed by a suitable deposition, such as chemical vapor deposition (CVD), atomic layer deposition (ALD), or the like. In the case, the first layers 104 are poly-SiGe layers, and the second layers 106 are poly-Si layers.

The first layers 104 and the second layers 106 may have the same or different thicknesses. In some embodiments, the first layers 104 have the same thickness T1 and the second layers 106 have the same thickness T2. In some embodiments, the thickness T1 ranges from about 5 nm to about 20 nm and the second thickness T2 ranges from about 5 nm to about 20 nm. Alternatively, the top to bottom first layers 104 may have different thicknesses, and the top to bottom second layers 106 may have different thicknesses.

The device 100 also includes a mask layer 108 formed on the semiconductor stack 102. The mask layer 108 may include a single-layered structure, a two-layered structure, or a multi-layered structure. For example, the mask layer 108 includes a silicon oxide (SiO) layer and a silicon nitlride (SiN) layer on the SiO layer. In some embodiments, the mask layer 108 is formed by CVD, ALD, or the like.

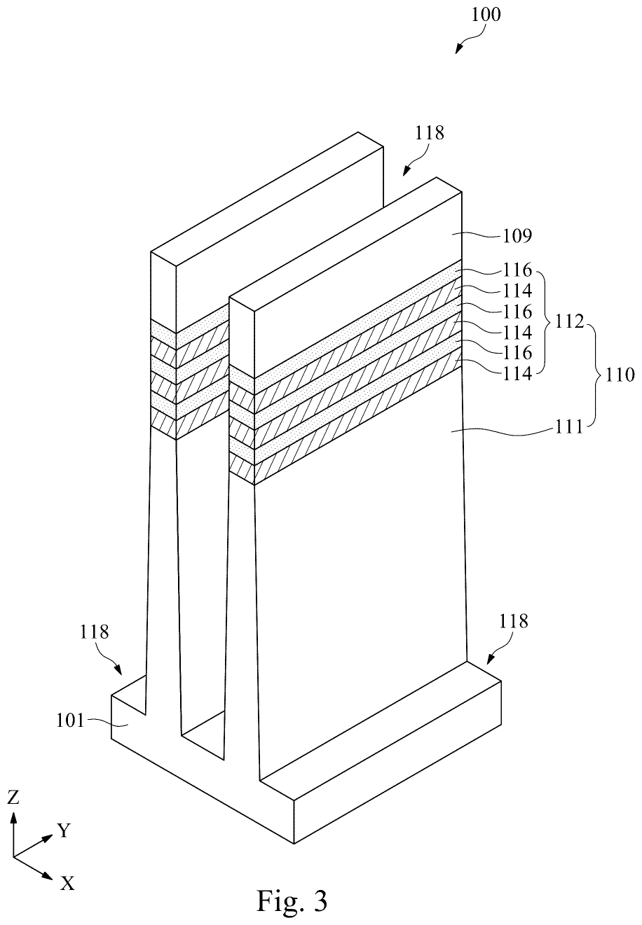

Referring to FIGS. 1 and 3, at operation 14, the method 10 patterns the mask layer 108, the semiconductor stack 102 of the first and second layers 104, 106, and a top portion of the substrate 101 to form fins 110. In some embodiments, the mask layer 108 is patterned to form a plurality of mask strips 109. The semiconductor stack 102 and the substrate 101 are then patterned by using the mask strips 109 as a mask, so as to form a plurality of trenches 118. In the case, a plurality of fin bases 111 and a plurality of stacks of semiconductor strips 112 on the fin bases 111 are formed between the trenches 118. The trenches 118 extend into the substrate 101, and have lengthwise directions parallel to each other. Herein, the stacks of semiconductor strips 112 are referred to as nanosheet stacks 112 and the combination of the fin bases 111 and the nanosheet stacks 112 thereon are referred to as fins 110. As shown in FIG. 3, the nanosheet stack 112 includes a plurality of first nanosheets 114 and a plurality of second nanosheets 116 stacked alternately along a Z-direction and extending along a Y direction.

In some embodiments, the fins 110 may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 110.

Although only two fins 110 are illustrated in FIG. 3, the embodiments of the present disclosure are not limited thereto. In other embodiments, the number of the fins 110 may be adjusted by the need, such as one fin, three fins, four fins, or more fins. In addition, the mask strips 109 illustrated in FIG. 3 have flat top surfaces. However, the embodiments of the present disclosure are not limited thereto. In other embodiments, the mask strips 109 may have dome top surfaces due to the high aspect ratio etching.

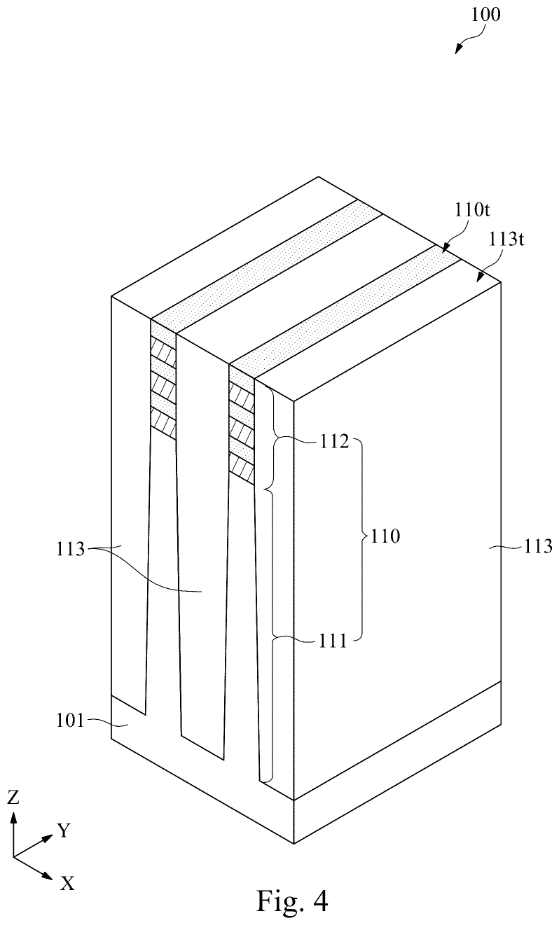

Referring to FIGS. 1 and 4, at operation 16, the method 10 forms insulating layer 113 in the trenches 118. In some embodiments, an insulating material is formed on the substrate 101 to cover the fins 110 and to fill up the trenches 118. In addition to the fins 110, the insulating material further covers the mask strips 109. The insulating material may include silicon oxide, silicon nitride, silicon oxynitride, a spin-on dielectric material, or a low-k dielectric material. Herein, the low-k dielectric materials are generally dielectric materials having a dielectric constant lower than 5.0, such as a dielectric constant lower than that of silicon oxide (about 3.9). The insulating material may be formed by flowable chemical vapor deposition (FCVD), high-density-plasma chemical vapor deposition (HDP-CVD), sub-atmospheric CVD (SACVD), or spin on. A planarization process may be performed, to remove a portion of the insulating material and the mask strips 109 until the fins 110 are exposed. In the case, as shown in FIG. 4, top surfaces 110t of the fins 110 are substantially coplanar with a top surface 113t of the planarized insulating layer 113. In some embodiments, the planarization process includes a chemical mechanical polish (CMP), an etching back process, a combination thereof, or the like.

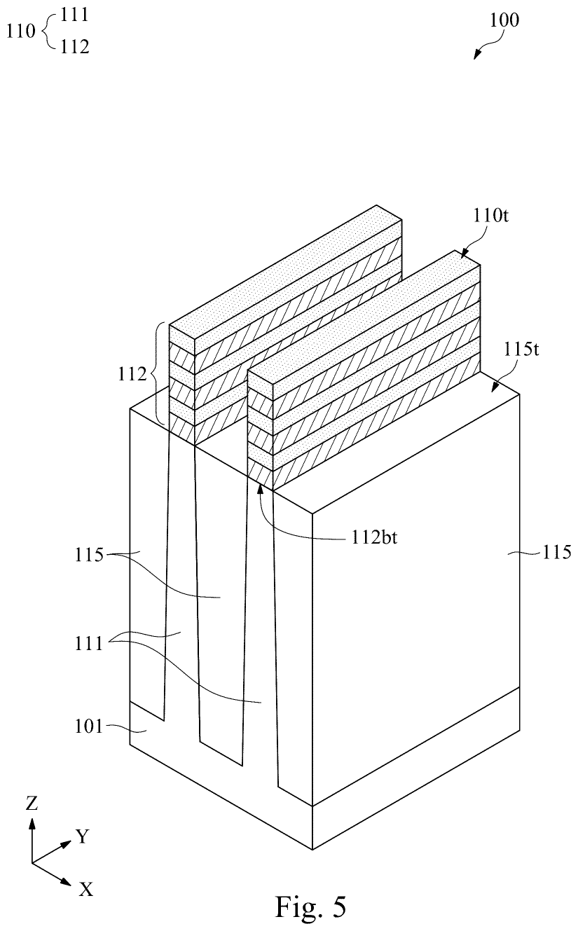

Referring to FIGS. 1 and 5, at operation 18, the method 10 recesses the insulating layer 113 to form a plurality of isolation regions 115. After recessing the insulating layers 113, the fins 110 protrude from top surfaces 115t of the isolation regions 115. That is, the top surfaces 115t of the isolation regions 115 may be lower than the top surfaces 110t of the fins 110. In some embodiments, the nanosheet stacks 112 are exposed by the isolation regions 115. That is, the top surfaces 115t of the isolation regions 115 may be substantially coplanar with or lower than bottom surfaces 112bt of the nanosheet stacks 112. Further, the top surfaces 115t of the isolation regions 115 may have a flat surface as illustrated, a convex surface, a concave surface (such as dishing), or a combination thereof. In some embodiments, the insulating layers 113 are recessed by using an appropriate etching process, such as a wet etching process with hydrofluoric acid (HF), a dry etching process, or a combination thereof. In some embodiments, a height difference between the top surfaces 110t of the fins 110 and the top surfaces 115t of the isolation regions 115 ranges from about 30 nm to about 100 nm. In some embodiments, the isolation regions 115 may be shallow trench isolation (STI) regions, deep trench isolation (DTI) regions, or the like.

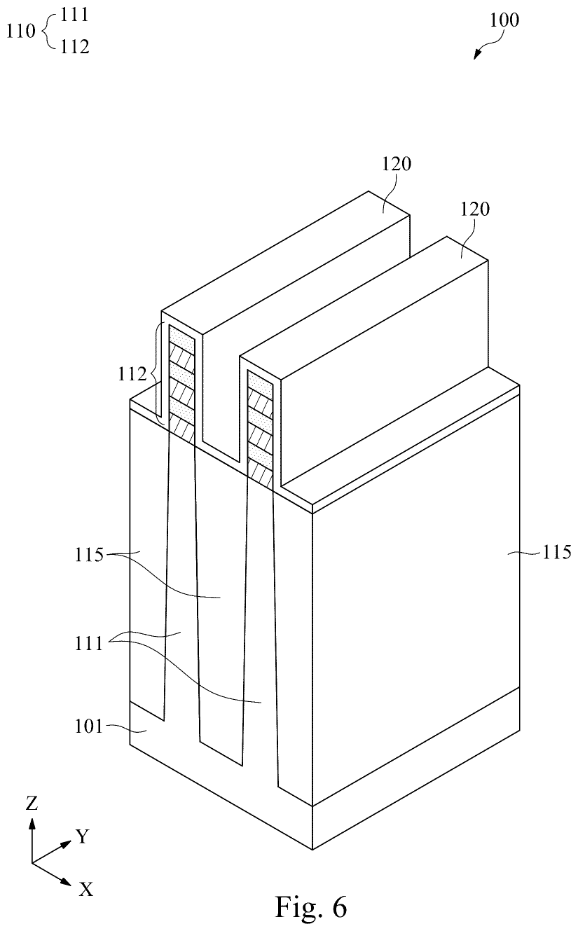

Referring to FIGS. 1 and 6, at operation 20, the method 10 forms a dummy dielectric layer 120 on the substrate 101. In some embodiments, the dummy dielectric layer 120 conformally covers the surfaces of the nanosheet stacks 112 and the top surfaces 115t of the isolation regions 115. In some embodiments, the dummy dielectric layer 120 includes silicon oxide, silicon nitride, silicon oxynitride, or the like, and may be formed by CVD, ALD or the like. The dummy dielectric layer 120 and the isolation regions 115 may have the same or different dielectric materials.

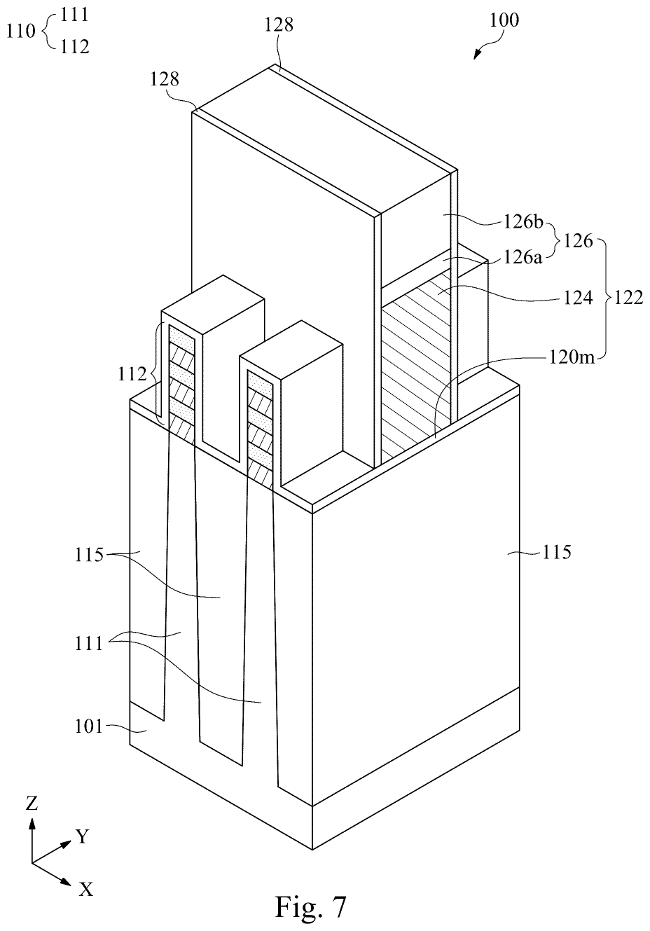

Referring to FIGS. 1 and 7, at operation 22, the method 10 forms a dummy gate stack 122 over portions of the nanosheet stacks 112 and portion of the isolation regions 115. The dummy gate stack 122 may extend along an X-direction perpendicular to the extending direction of the nanosheet stacks 112. That is, the dummy gate stack 122 may be formed across the nanosheet stacks 112. Specifically, the dummy gate stack 122 may include dummy gate electrode 124 and a portion of the dummy dielectric layer 120 covered by the dummy gate electrode 124. Herein, the portion of the dummy dielectric layer 120 covered by the dummy gate electrode 124 is referred to as dummy gate dielectric layer 120m. In some embodiments, the dummy gate electrode 124 includes a silicon-containing material, such as poly-silicon, amorphous silicon, or a combination thereof. The dummy gate electrode 124 may be formed by using a suitable process, such as ALD, CVD, PVD, plating, or combinations thereof. Although the dummy gate electrode 124 illustrated in FIG. 7 is a single-layered structure, the embodiments of the present disclosure are not limited thereto. In other embodiments, the dummy gate electrode 124 may be a multi-layered structure. The dummy gate stack 122 may also include hard mask layer 126 over dummy gate electrode 124. In some embodiments, the hard mask layer 126 includes a single-layered structure, a two-layered structure, a multi-layered structure. For example, as in FIG. 7, the hard mask layer 126 includes a silicon oxide layer 126a and a silicon nitride layer 126b disposed over the silicon oxide layer 126a.

Still referring to FIG. 7, gate spacers 128 are also formed on sidewalls of the dummy gate stack 122. Similar to the dummy gate stack 122, the gate spacers 128 are also formed across the nanosheet stacks 112. In some embodiments, the gate spacers 128 are formed of one or more dielectric materials, such as SiCN, SiC, SiOCN, SiOC, SiON, or a combination thereof. In furtherance of some embodiments, the gate spacers 128 may comprise a low-k material having a k-value less than about 5.0, such as about 3.9 or even less. For example, in some embodiments the gate spacers 128 may include a porous dielectric material, an extreme low-k (ELK) dielectric material (e.g., SiCOH), and the like. The gate spacers 128 may or may not include air gaps (not illustrated) to further reduce its k-value. The low-k material of the gate spacers 128 is used to advantageously reduce parasitic capacitance between subsequently formed metal gate structure and source/drain contact(s) particularly in advanced node technologies where the metal gate structure and source/drain contact(s) are in close proximity. A thickness of the gate spacers 128 ranges from about 1 nm to about 10 nm in some embodiments. Although the gate spacers 128 illustrated in FIG. 7 is a single-layered structure, the embodiments of the present disclosure are not limited thereto. In other embodiments, the gate spacers 128 may be a multi-layered structure. For example, the spacer 128 may include a silicon oxide layer and a silicon nitride layer disposed on the silicon oxide layer. The dummy gate stack 122 and the gate spacers 128 cover middle portions of the nanosheet stacks 112, and reveal the opposite end portions not covered.

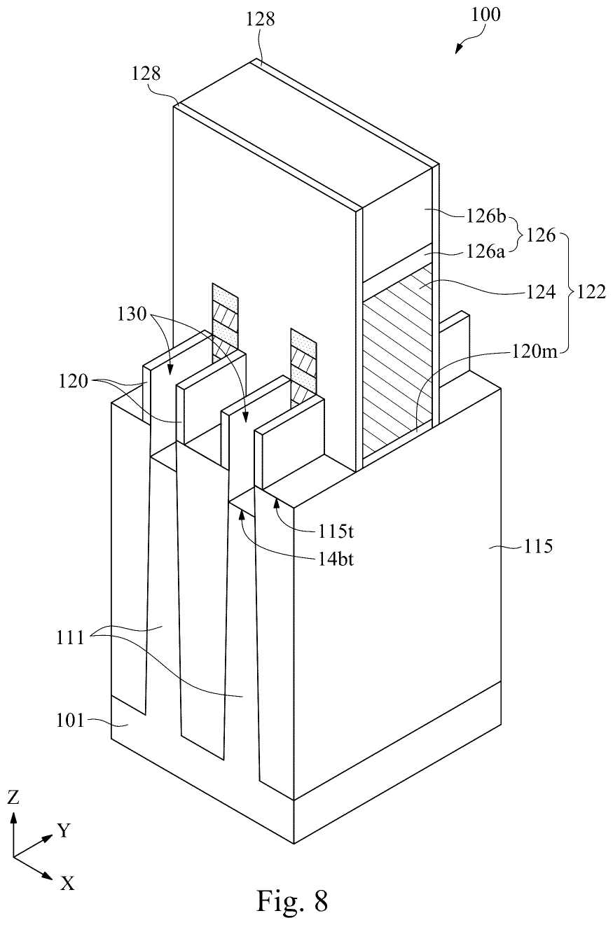

Referring to FIGS. 1 and 8, at operation 24, the method 10 recesses the end portions of the nanosheet stacks 112 to form recesses 130. Herein, the recesses 130 may be referred to as source/drain recesses 130. In some embodiments, the end portions of the nanosheet stacks 112 may be removed by an anisotropic etching process, an isotropic etching process, or a combination thereof. In some embodiments, the source/drain recesses 130 further extend into the fin bases 111 and are lower than the top surfaces 115t of the isolation regions 115. In other words, the end portions of the nanosheet stacks 112 are entirely removed and top portions of the fin bases 111 are further removed. In the case, as shown in FIG. 8, the bottom surfaces 14bt of the source/drain recesses 130 are lower than the top surfaces 115t of the isolation regions 115. In some embodiments, some portions of the dummy dielectric layer 120 are removed and other portions of the dummy dielectric layer 120 may be left standing over and aligned to the edges of isolation regions 115, with the source/drain recesses 130 formed therebetween. The gate spacers 128 may cover sidewalls of the dummy gate stack 122 which includes the dummy gate dielectric layer 120m, the dummy gate electrode 124, and the hard mask layer 126.

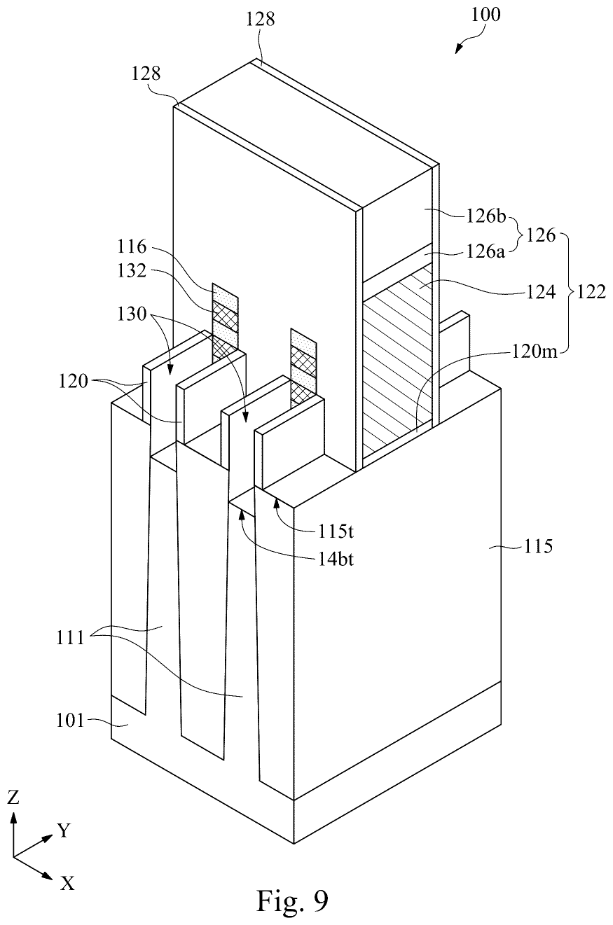

Referring to FIGS. 1 and 9, at operation 26, the method 10 forms inner spacers 132 at opposite end portions of the first nanosheets 114. In some embodiments, opposite end portions of the first nanosheets 114 as exposed in the source/drain recesses 130 are selectively and partially recessed to form inner spacer recesses (not shown), while the second nanosheets 116 are substantially unetched. In an embodiment where the second nanosheets 116 consist essentially of silicon (Si) and the first nanosheets 114 consist essentially of silicon germanium (SiGe), the selective and partial recess of the first nanosheets 114 may include a SiGe oxidation process followed by a SiGe oxide removal. The SiGe oxidation process may include use of ozone (O₃). In some other embodiments, the selective recess may be a selective isotropic etching process (e.g., a selective dry etching process or a selective wet etching process), and the extent at which the first nanosheets 114 are recessed is controlled by duration of the etching process. The selective dry etching process may include use of one or more fluorine-based etchants, such as fluorine gas or hydrofluorocarbons. The selective wet etching process may include a hydro fluoride (HF) or NH₄OH etchant. After the formation of the inner spacer recesses, an inner spacer material layer is deposited over the semiconductor device 100, including in the inner spacer recesses. The inner spacer material layer may include silicon oxide, silicon nitride, silicon oxycarbide, silicon oxycarbonitride, silicon carbonitride, metal nitride, or a suitable dielectric material. The deposited inner spacer material layer is then etched back to remove excess inner spacer material layer over the gate spacers 128 and sidewalls of the second nanosheets 116, thereby forming the inner spacers 132.

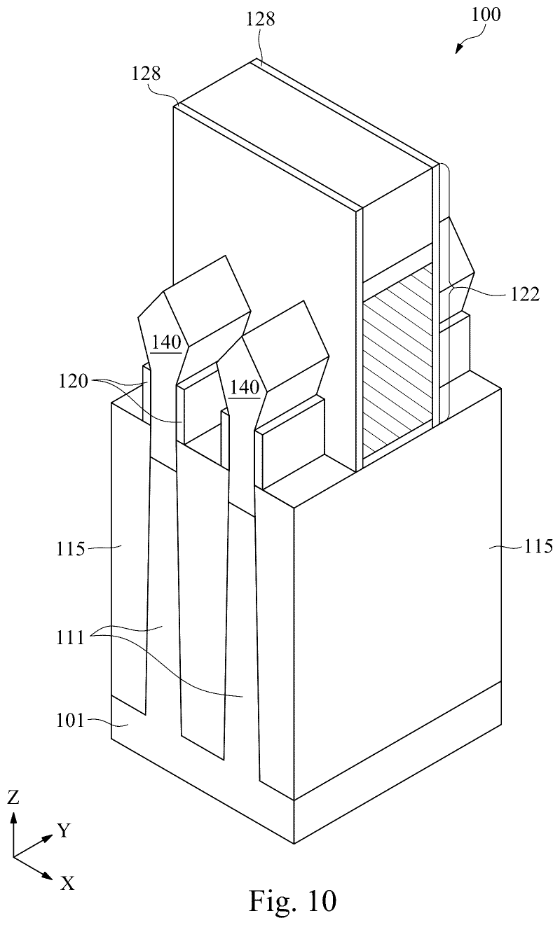

Referring to FIGS. 1 and 10, at operation 28, the method 10 epitaxially grows a strained material 140 (or a highly doped low resistance material) from the source/drain recesses 130. In some embodiments, the strained material 140 is used to strain or stress the second nanosheets 116 and the fin bases 111. Herein, the strained material 140 may be referred to as source/drain regions 140 or source/drain features 140. In the case, the strained material 140 includes a source disposed at one side of the dummy gate stack 122 and a drain disposed at another side of the dummy gate stack 122. The source covers an end of the fin bases 111, and the drain covers another end of the fin bases 111. The source/drain regions 140 are abutted and electrically connected to the second nanosheets 116, while the source/drain regions 140 are electrically isolated from the first nanosheets 114 by the inner spacers 132. In some embodiments, the source/drain regions 140 extend beyond the top surface of the nanosheet stacks 112. However, the embodiments of the present disclosure are not limited thereto, in other embodiments, the top surface of the source/drain regions 140 is substantially aligned with the top surface of the nanosheet stacks 112.

The source/drain regions 140 include any acceptable material, such as appropriate for p-type transistors or n-type transistors. For example, the source/drain regions 140 may include SiGe, SiGeB, Ge, GeSn, or the like, which is appropriate for p-type transistors. In some alternative embodiments, the source/drain regions 140 may include silicon, SiC, SiCP, SiP, or the like, which is appropriate for n-type transistors. In some embodiments, the source/drain regions 140 are formed by MOCVD, MBE, ALD, or the like. The source/drain regions 140 may comprise one or more semiconductor material layers. For example, the source/drain regions 140 may comprise a bottom semiconductor material layer, a middle semiconductor material layer, and a capping semiconductor material layer. Any number of semiconductor material layers may be used for the source/drain regions 140. Each of the semiconductor material layers may be formed of different semiconductor materials and may be doped to different dopant concentrations. In embodiments in which the source/drain regions 140 comprise three semiconductor material layers, the bottom semiconductor material layer may be deposited, the middle semiconductor material layer may be deposited over the bottom semiconductor material layer, and the capping semiconductor material layer may be deposited over the middle semiconductor material layer.

In some embodiments, the source/drain regions 140 are doped with a conductive dopant. For example, the source/drain regions 140, such as SiGe, may be epitaxial-grown with a p-type dopant for straining a p-type transistor. That is, the source/drain regions 140 are doped with the p-type dopant to be the source and the drain of the p-type transistor. The p-type dopant includes boron or BF₂, and the source/drain regions 140 may be epitaxial-grown by LPCVD process with in-situ doping. As discussed above, the source/drain regions 140 may be epitaxially-grown with multiple layers differed in dopant concentrations, such as a bottom layer of SiGe:B with Ge atomic percentage from about 45% to 55% and a boron concentration of about 1×10²¹/cm³ to about 2×10²¹/cm³, a middle layer of SiGe:B with Ge atomic percentage from about 45% to 60% and a boron concentration of about 8×10²⁰/cm³ to about 3×10²¹/cm³, and a capping layer of SiGe:B with Ge atomic percentage from about 25% to 45% and a boron concentration of about 1×10²⁰/cm³ to about 8×10²⁰/cm³. In some alternative embodiments, the source/drain regions 140, such as SiC, SiP, a combination of SiC/SiP, or SiCP is epitaxial-grown with an n-type dopant for straining an n-type transistor. That is, the source/drain regions 140 are doped with the n-type dopant to be the source and the drain of the n-type transistor. The n-type dopant includes arsenic and/or phosphorus, and the source/drain regions 140 may be epitaxial-grown by LPCVD process with in-situ doping. In some embodiments, the source/drain regions 140 are epitaxially-grown with multiple layers differed in dopant concentrations, such as a bottom layer of Si:P with a phosphorus concentration of about 1×10²¹/cm³ to about 2×10²¹/cm³, a middle layer of Si:P with a phosphorus concentration of about 1×10²¹/cm³ to about 4×10²¹/cm³, and a capping layer of Si:As with an arsenic concentration of about 1×10²⁰/cm³ to about 1×10²¹/cm³.

As a result of the epitaxial-grown process used to form the source/drain regions 140, the cross section of the source/drain regions 140 may have a diamond or pentagonal shape. However, the embodiments of the present disclosure are not limited thereto. In other embodiments, the cross section of the source/drain regions 140 also have a hexagonal shape, a pillar shape, or a bar shape. In some embodiments, as shown in FIG. 10, adjacent source/drain regions 140 are separated from each other after the epitaxial-grown process is completed. Alternatively, adjacent source/drain regions 140 may be merged.

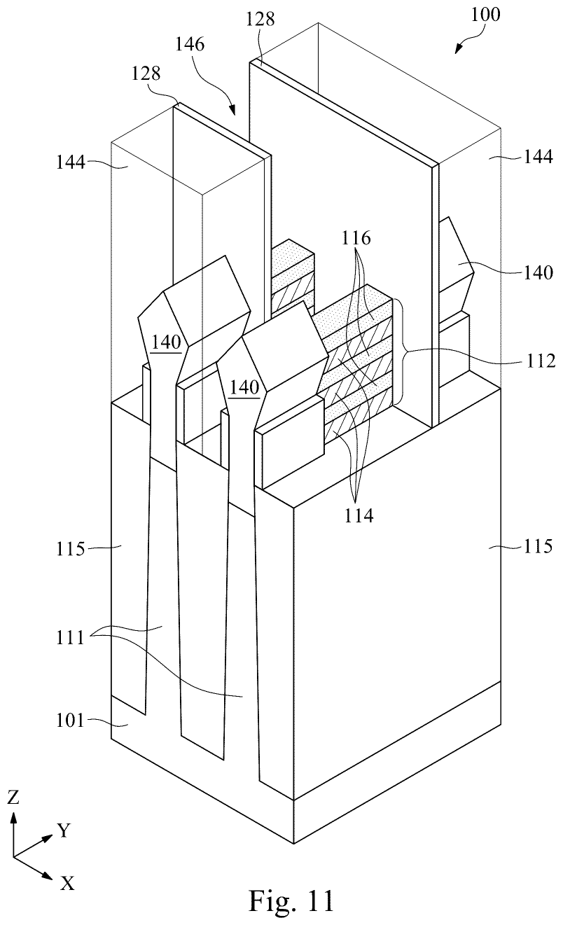

Referring to FIGS. 1 and 11, at operation 30, the method 10 forms an interlayer dielectric (ILD) layer 144 over the device 100. A contact etch stop layer (CESL) may also be formed between the source/drain regions 140 and the ILD layer 144. For clarity, the CESL is not illustrated in FIG. 11. In addition, in order to illustrate the features behind the front portion of the ILD layer 144, some front portions of the ILD layer 144 are not shown in FIG. 11 and subsequent figures, so that the inner features may be illustrated. It is appreciated that the un-illustrated portions of the ILD layer 144 still exist.

In some embodiments, the CESL conformally covers the source/drain regions 140 and the sidewalls of the outer sidewalls of the gate spacers 128. The CESL may include silicon nitride, silicon oxynitride, silicon nitride with oxygen (O) or carbon (C) elements, and/or other materials; and may be formed by CVD, PVD (physical vapor deposition), ALD, or other suitable methods.

The ILD layer 144 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), SiOCN, SiOC, SiC, polyimide, and/or a combination thereof. In some other embodiments, the ILD layer 144 includes low-k dielectric materials. Examples of low-k dielectric materials include BLACK DIAMOND® (Applied Materials of Santa Clara, Calif.), Xerogel, Aerogel, amorphous fluorinated carbon, Parylene, BCB (bis-benzocyclobutenes), Flare, SILK® (Dow Chemical, Midland, Mich.), hydrogen silsesquioxane (HSQ) or fluorinated silicon oxide (SiOF), and/or a combination thereof. In alternative embodiments, the ILD layer 144 include one or more dielectric materials and/or one or more dielectric layers. In some embodiments, the ILD layer 144 is formed to a suitable thickness by FCVD, CVD, HDPCVD, SACVD, spin-on, sputtering, or other suitable methods. For example, an interlayer dielectric material layer is initially formed to cover the isolation regions 115, the dummy gate stack 122, and the gate spacers 128. Subsequently, a thickness of the interlayer dielectric material layer is reduced until the dummy gate stack 122 is exposed, so as to form the ILD layer 144. The process of reducing the thickness of the interlayer dielectric material layer may be achieved by a chemical mechanical polishing (CMP) process, an etching process, or other suitable processes. In the case, the top surface of the ILD layer 144 may be coplanar with the top surface of the dummy gate stack 122.

Still referring to FIGS. 1 and 11, at operation 32, the method 10 removes the dummy gate stack 122 to form a gate trench 146. The ILD layer 144 and the CESL may protect the source/drain regions 140 during removing the dummy gate stack 122. The dummy gate stack 122 may be removed by using plasma dry etching and/or wet etching. When the dummy gate electrode is polysilicon and the ILD layer 144 is silicon oxide, a wet etchant such as a TMAH solution may be used to selectively remove the dummy gate electrode. The dummy gate dielectric layer is thereafter removed by using another plasma dry etching and/or wet etching.

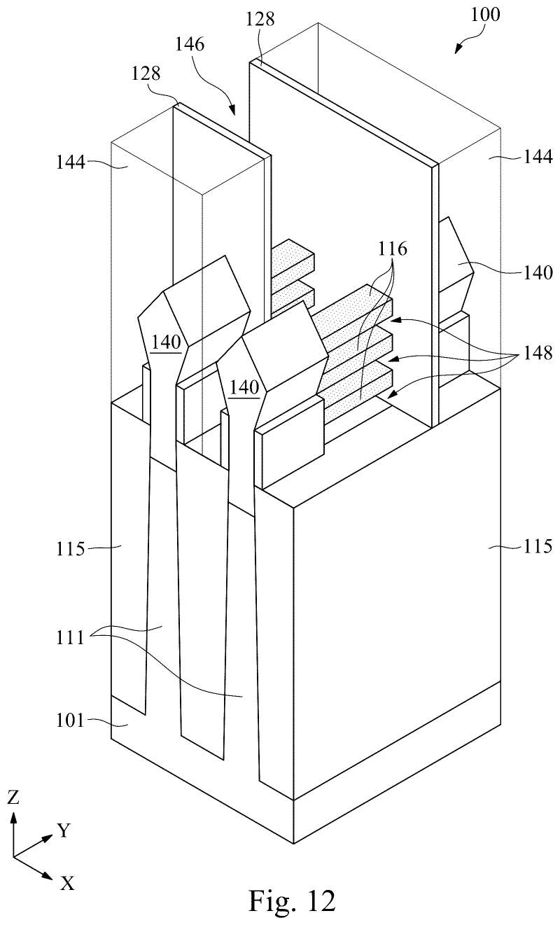

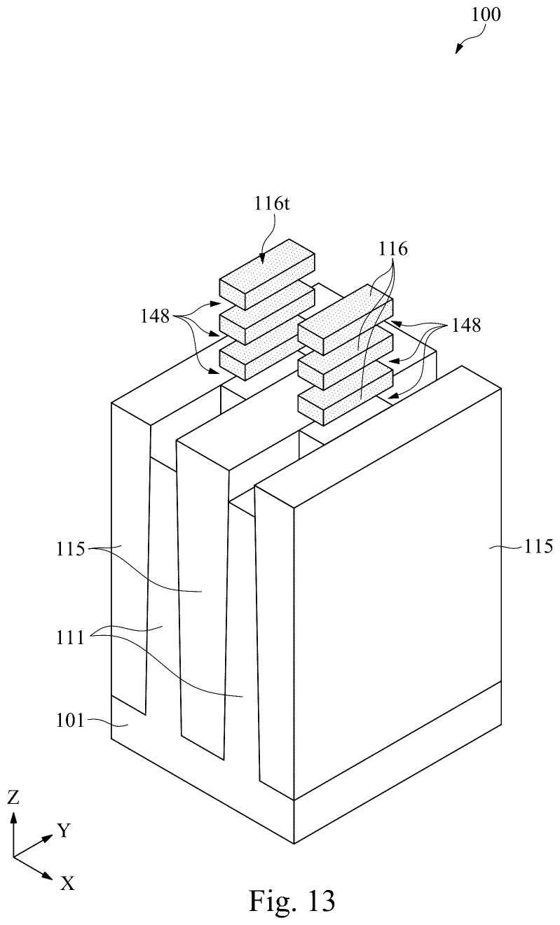

Referring to FIGS. 1 and 12, at operation 34, the method 10 performs an etching process to remove the first nanosheets 114. In the case, the first nanosheets 114 may be completely removed to form a plurality of gaps 148 between the second nanosheets 116, also as shown in FIG. 13. FIG. 13 illustrates a clearer view of the portions of stacked nanosheets 116. The ILD 144, the source/drain regions 140, and the gate spacers 128 as shown in FIG. 12 are not shown in FIG. 13, although these features still exist. Accordingly, the second nanosheets 116 are separated from each other by the gaps 148. In addition, the bottommost second nanosheet 116 may also be separated from the fin bases 111 by the gaps 148. As a result, the second nanosheets 116 are suspended. A height of the gaps 148 ranges from about 5 nm to about 20 nm in some embodiments. In the present embodiment, the second nanosheets 116 include silicon, and the first nanosheets 114 include silicon germanium. The first nanosheets 114 may be selectively removed by oxidizing the first nanosheets 114 using a suitable oxidizer, such as ozone. Thereafter, the oxidized first nanosheets 114 may be selectively removed from the gate trench 146. In some embodiments, the etching process includes a dry etching process to selectively remove the first nanosheets 114, for example, by applying an HCl gas at a temperature of about 20° C. to about 300° C., or applying a gas mixture of CF₄, SF₆, and CHF₃. The opposite ends of the suspended second nanosheets 116 are connected to source/drain regions 140. The suspended second nanosheet 116 may be referred to as channel members 116 hereinafter. The etching process may be referred to as channel member releasing process. The top surface 110t of the fin 110 thereon is referred to as the channel top surface 116t, which is the top surface of the topmost channel member 116.

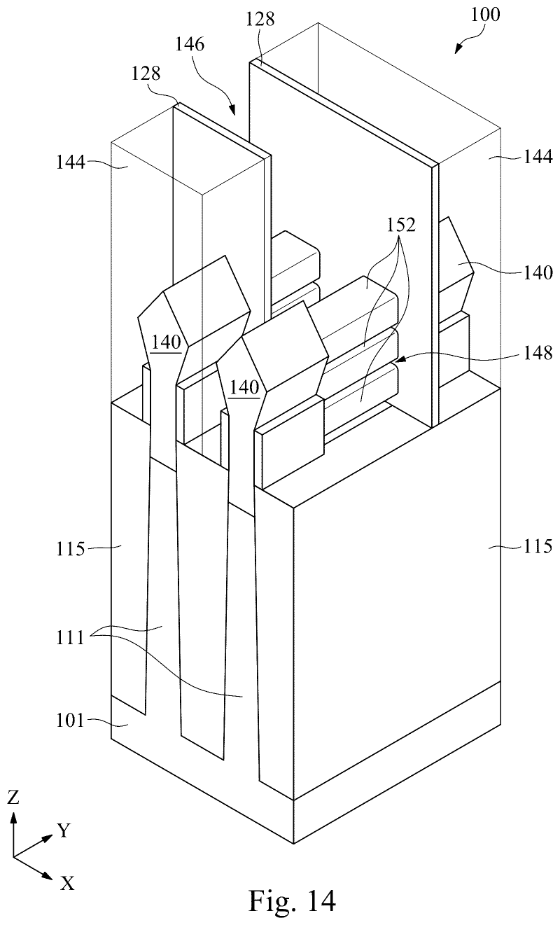

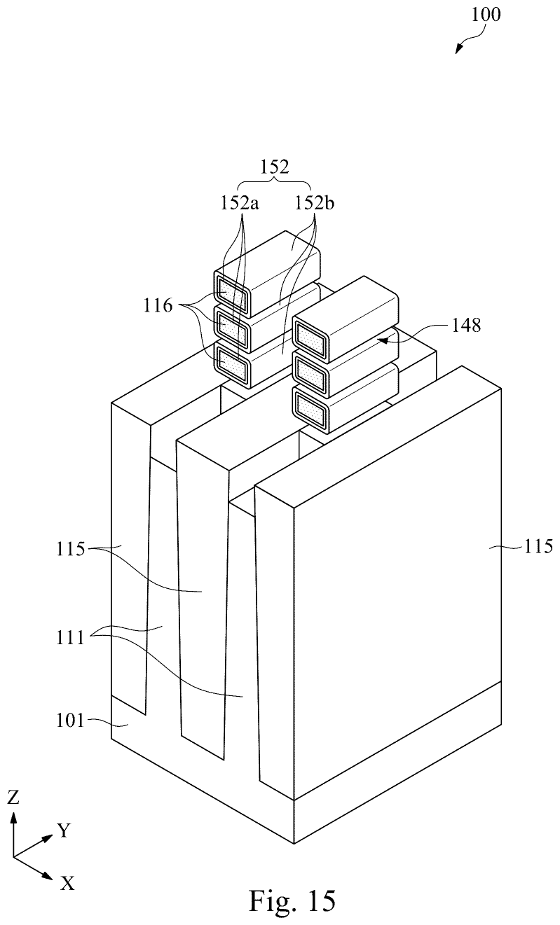

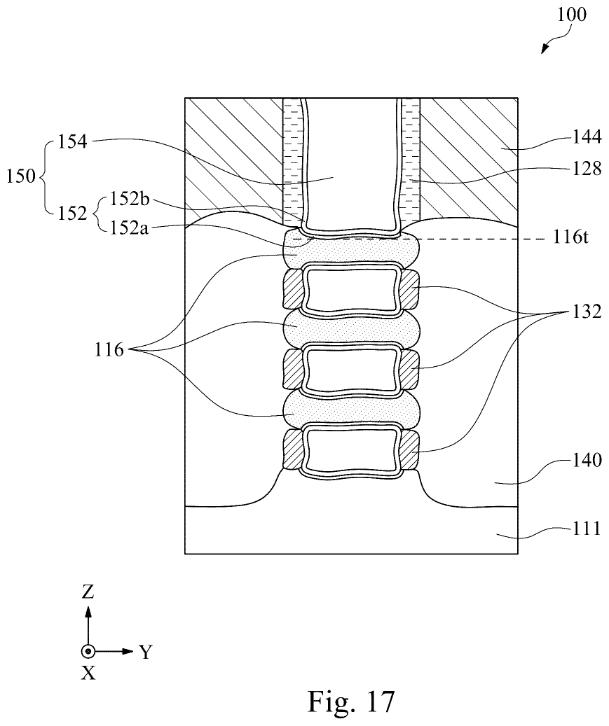

Referring to FIGS. 1 and 14, at operation 36, the method 10 forms a gate dielectric layer 152 in the gate trench 146 and the gaps 148. FIG. 15 illustrates a clearer view of the gate dielectric layer 152 wrapping the channel members 116. In some embodiments, the gate dielectric layer 152 includes an interfacial layer 152a formed on the surfaces of the channel members 116 and the top surface of the fin base 111, and a high-k dielectric layer 152b wrapping the interfacial layer 152a and the channel members 116 underneath. The high-k dielectric layer 152b is also disposed on opposing sidewall surfaces of the gate spacers 128 in the gate trench 146 (as shown in FIG. 17). The interfacial layer 152a is very thin and is made of, for example, SiO₂, SiOx (0<x<2), or a combination thereof. In some embodiments, the interfacial layer 152a is formed by applying an oxidizing agent on the surfaces of the channel members 116. For example, a hydrogen peroxide-containing liquid may be applied or provided on the surfaces of the channel members 116, so as to form the interfacial layer 152a. The high-k dielectric layer 152b may include a dielectric material with high dielectric constant. Examples of high-k dielectric material include HfO₂, HfSiO, HfSiON, HfTaO, HfTiO, HfZrO, zirconium oxide, lanthanum oxide, aluminum oxide, titanium oxide, hafnium dioxide-alumina (HfO₂-Al₂O₃) alloy, other suitable high-k dielectric materials, and/or combinations thereof. The high-k dielectric layer 152b may be formed by CVD, ALD or any suitable method. In one embodiment, the high-k dielectric layer 152b is formed by using a highly conformal deposition process, such as ALD in order to ensure the formation of a high-k dielectric layer having a uniform thickness around each channel member 116. A thickness of the high-k dielectric layer 152b ranges from about 0.5 nm to about 3 nm in some embodiments.

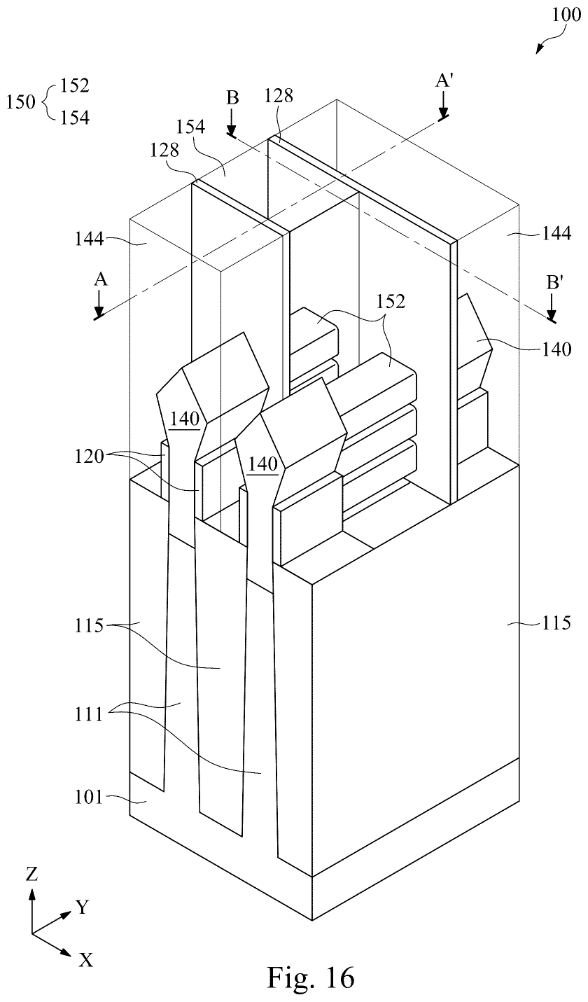

Referring to FIGS. 1 and 16, at operation 38, the method 10 forms a gate electrode 154 on the gate dielectric layer 152 and then planarized by using, for example, a CMP process, until the top surface of the ILD layer 144 is revealed. FIG. 17 corresponds to a fragmentary cross-sectional view of the device 100 in FIG. 16 taken along the line A-A′. In the case, the gate electrode 154 and the gate dielectric layer 152 constitute a gate stack 150. The gate electrode 154 may include various conductive materials, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode 154 may include one or more layers of conductive materials, such as a work function layer and a metal filling layer (not separately shown). The metal filling layer functions as a conductive filler that completely fills the remaining space of the gate trench 146.

The work function layer may be used to provide the desired work function for transistors to enhance device performance including improved threshold voltage. In some embodiments, the work function layer is used for forming a PMOS device. The work function layer is a p-type work function layer. The p-type work function layer is capable of providing a work function value suitable for the device, such as equal to or greater than about 4.8 eV. The p-type work function layer may include metal, metal carbide, metal nitride, other suitable materials, or a combination thereof. For example, the p-type metal includes tantalum nitride, tungsten nitride, titanium, titanium nitride, one or more other suitable materials, or a combination thereof. In some other embodiments, the work function layer is used for forming an NMOS device. The work function layer is an n-type work function layer. The n-type work function layer is capable of providing a work function value suitable for the device, such as equal to or less than about 4.5 eV. The n-type work function layer may include metal, metal carbide, metal nitride, or a combination thereof. For example, the n-type work function layer includes titanium nitride, tantalum, tantalum nitride, one or more other suitable materials, or a combination thereof. In some embodiments, the n-type work function layer is an aluminum-containing layer. The aluminum-containing layer may be made of or include TiAlC, TiAlO, TiAlN, one or more other suitable materials, or a combination thereof. The work function layer may also be made of or include hafnium, zirconium, titanium, tantalum, aluminum, metal carbides (e.g., hafnium carbide, zirconium carbide, titanium carbide, aluminum carbide), aluminides, ruthenium, palladium, platinum, cobalt, nickel, conductive metal oxides, or combinations thereof. The thickness and/or the compositions of the work function layer may be fine-tuned to adjust the work function level. The work function layer may be deposited over the gate dielectric layer 152 using an ALD process, a CVD process, a PVD process, an electroplating process, an electroless plating process, one or more other applicable processes, or a combination thereof.

In some embodiments, a barrier layer (not shown) is formed before the work function layer to interface the gate dielectric layer 152 with the subsequently formed work function layer. The barrier layer may also be used to prevent diffusion between the gate dielectric layer 152 and the subsequently formed work function layer. The barrier layer may be made of or include a metal-containing material. The metal-containing material may include titanium nitride, tantalum nitride, one or more other suitable materials, or a combination thereof. The barrier layer may be deposited using an ALD process, a CVD process, a PVD process, an electroplating process, an electroless plating process, one or more other applicable processes, or a combination thereof.

In some embodiments, the metal filling layer is made of or includes a metal material. The metal material may include tungsten, ruthenium, aluminum, copper, cobalt, titanium, TiN, TiAl, TiAlC, one or more other suitable materials, or a combination thereof. The metal filling layer may be deposited over the work function layer using a CVD process, an ALD process, a PVD process, an electroplating process, an electroless plating process, a spin coating process, one or more other applicable processes, or a combination thereof.

In some embodiments, a blocking layer (not shown) is formed over the work function layer before the formation of the conductive layer. The blocking layer may be used to prevent the subsequently formed metal filling layer from diffusing or penetrating into the work function layer. The blocking layer may be made of or include tantalum nitride, titanium nitride, one or more other suitable materials, or a combination thereof. The blocking layer may be deposited using an ALD process, a PVD process, an electroplating process, an electroless plating process, one or more other applicable processes, or a combination thereof.

In some embodiments, the metal filling layer does not extend into the gaps 148 since the gaps 148 are small and have been filled with other features such as the gate dielectric layer 152 and the work function layer. In furtherance of some embodiments, a bottom surface of the metal filling layer may be above the channel top surface 116t in the fragmentary cross-sectional view along the line A-A′ represented by FIG. 17. However, embodiments of the disclosure are not limited thereto. In some other embodiments, a portion of the metal filling layer extends into the gaps 148 with larger space.

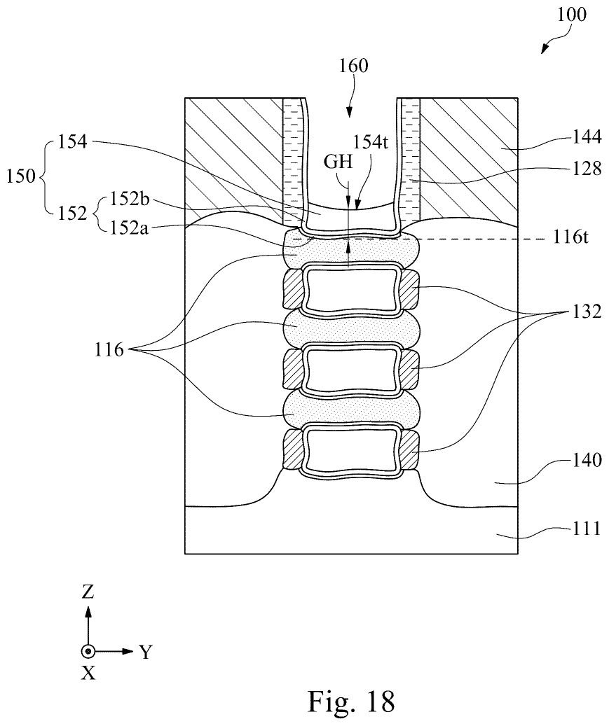

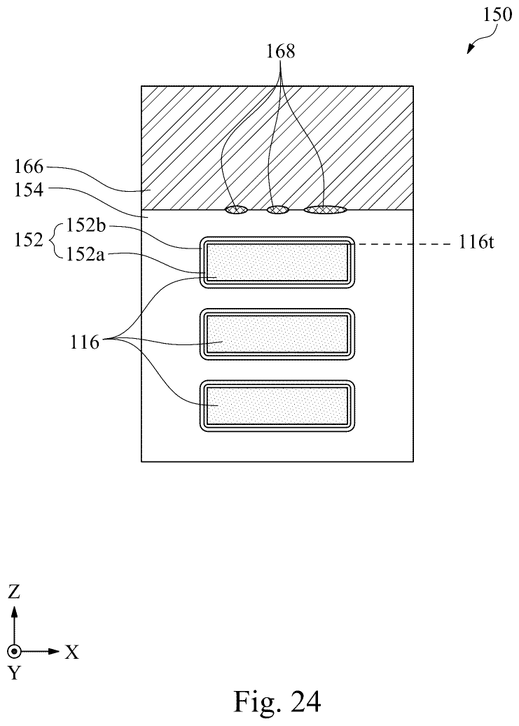

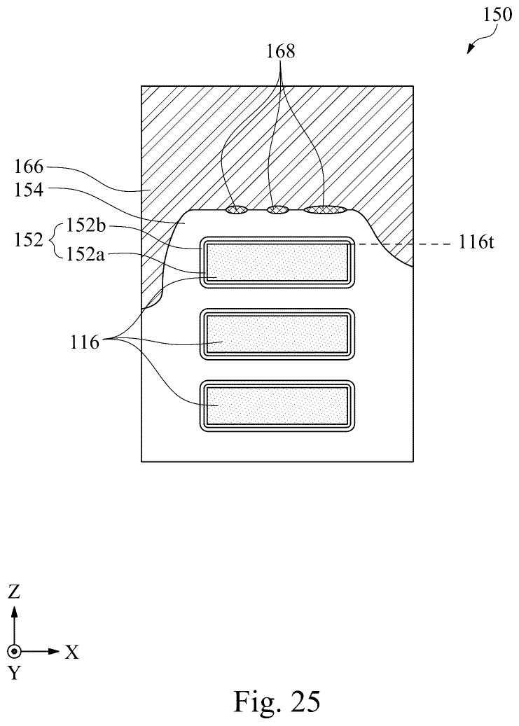

For clarity, subsequent steps of the method 10 in forming the device 100 are described in conjunction with FIGS. 18-30, in which FIGS. 18-23 and 26-30 correspond to fragmentary cross-sectional views of the device 100 in FIG. 16 along the line A-A′ and FIGS. 24-25 correspond to fragmentary cross-sectional views of the device 100 in FIG. 16 along the line B-B′.

Referring to FIGS. 1 and 18, at operation 40, the method 10 etches back the gate electrode 154 to form a recess 160. In some embodiments, the etch back process may be a dry etch process that includes use of an oxygen-containing gas, hydrogen, nitrogen, a fluorine-containing gas (e.g., CF₄, SF₆, CH₂F₂, CHF₃, CH₃F, C₄F₆, and/or C₂F₆), a chlorine-containing gas (e.g., Cl₂, CHCl₃, CCl₄, and/or BCl₃), a bromine-containing gas (e.g., HBr and/or CHBR₃), an iodine-containing gas (e.g., CF₃I), other suitable gases and/or plasmas, and/or combinations thereof. The etchants are selected such that the high-k dielectric layer 152b is substantially intact and remains on opposing sidewall surfaces of the gate spacers 128. The recessed top surface 154t of the gate electrode 154 may have a concave (e.g., dishing) profile. The remaining gate height (denoted as GH, measured from a bottom of the concave shape to the channel top surface 116t) is in a range from about 1 nm to about 20 nm in some embodiments.

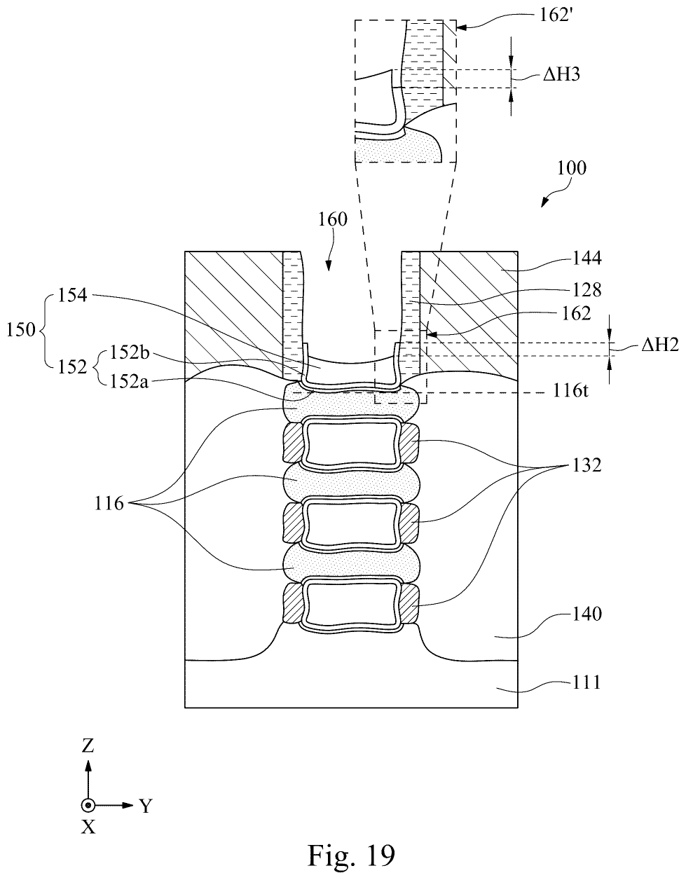

Referring to FIGS. 1 and 19, at operation 42, the method 10 etches back the high-k dielectric layer 152b to expose the opposing sidewall surfaces of the gate spacers 128 in the recess 160. In some embodiments, the insulating layers 113 are recessed by using an appropriate etching process, such as a selective wet etching process, a selective dry etching process, or a combination thereof. The selective dry etching process may include use of one or more fluorine-based etchants, such as fluorine gas or hydrofluorocarbons. The selective wet etching process may include a hydro fluoride (HF) or NH₄OH etchant. The etchants are selected such that the gate spacers 128 and the recessed gate electrode 154 are substantially intact. The etched back amount of the high-k dielectric layer 152b may be controlled by an etching timer. In some embodiments, as illustrated in the corner region 162 highlighted by the dashed box, the high-k dielectric layer 152b may have a protruding portion above the recessed top surface 154t for a vertical distance ΔH2. In various embodiments, ΔH2 is less than about 2 nm. ΔH2 being less than about 2 nm is not arbitrary. If the protruding portion of the high-k dielectric layer 152b is larger than about 2 nm, the remaining high-k material between the metal gate structure and the subsequently formed source/drain contact is still too much and increases parasitic capacitance. In some other embodiments, as also illustrated in FIG. 19 as in the alternative corner region 162′, the high-k dielectric layer 152b may be recessed below the recessed gate electrode 154 for a vertical distance ΔH3. In some embodiments, a range of ΔH3 may be from about 0.1 nm to about 2 nm. In furtherance of some embodiments, the recessed top surface of the high-k dielectric layer 152b is further below a bottommost point of the concave shape of the recessed top surface 154t of the recessed gate electrode 154. In some embodiments, operations 40 and 42 may be performed simultaneously, such that the gate electrode 154 and the high-k dielectric layer 152b are recessed together by the etching process.

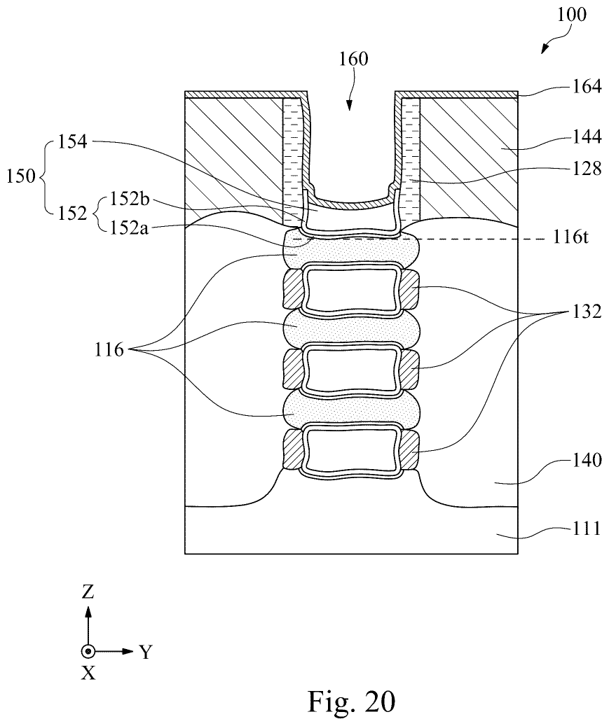

Referring to FIGS. 1 and 20, at operation 44, the method 10 deposits a low-k spacer layer 164 over bottom and sidewall surfaces of the recess 160 and also over the top surfaces of the ILD layer 144. The low-k spacer layer 164 covers the high-k dielectric layer 152b and the recessed gate electrode 154. The low-k spacer layer 164 may comprise a low-k material having a k-value less than about 5.0, such as less than about 3.9 or even less than about 2.5. For example, in some embodiments the low-k spacer layer 164 may include carbonized silicon nitride (SiCN), SiONC, a porous dielectric material, an extreme low-k (ELK) dielectric material (e.g., SiCO, SiCOH), and the like. The low-k spacer layer 164 may optionally include air gaps (not illustrated) to further reduce its k-value. In one example, the dielectric constant of a porous low-k dielectric material is less than about 2.0. The low-k dielectric material of the low-k spacer layer 164 replaces the otherwise high-k dielectric material of the high-k dielectric layer 152b and is used to advantageously reduce parasitic capacitance between metal gate structure and subsequently formed source/drain contact. In some embodiments, the gate spacers 128, the low-k spacer layer 164, and the high-k dielectric layer 152b include different dielectric materials from each other. Regarding dielectric constants, the k-value of the low-k spacer layer 164 may be smaller or higher than the k-value of the gate spacers 128 depending on particular device performance considerations, which are both smaller than the k-value of the high-k dielectric layer 152b. In some embodiments, the low-k spacer layer 164 is blanket (or conformally) deposited, such as in an ALD process during which precursors for forming the low-k spacer layer 164 are applied in a cyclic fashion. Thickness of the low-k spacer layer 164 may be controlled by tuning the number of deposition cycles performed in a deposition chamber during an ALD process. In some embodiments, a thickness of the low-k spacer layer 164 ranges from about 0.5 nm to about 1.5 nm.

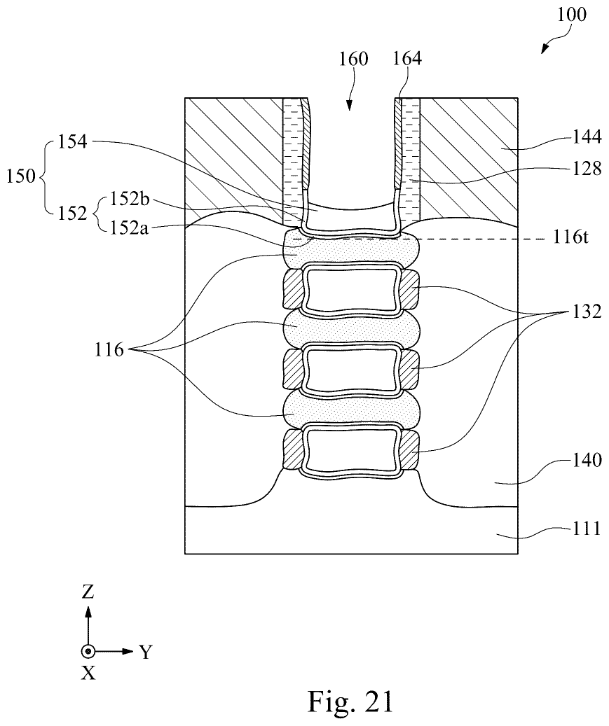

Referring to FIGS. 1 and 21, at operation 46, the method 10 performs an etching process for breaking through, and removing the majority of, the horizontal portions of the low-k spacer layer 164. The etching process is also referred to as a breakthrough (BT) etching process. In some embodiments, the BT etching process may include an anisotropic dry etch process, or the like. In some embodiments, the BT etch process is a reactive ion etch (RIE) process with etch process gases including CHF₃, Ar, CF₄, N₂, O₂, CH₂F₂, SF₃, the like, or a combination thereof. The RIE process may be performed for an etch time between about 2 seconds and about 20 seconds, at a pressure between about 2 mTorr and about 30 mTorr, a temperature between about 10° C. and about 100° C., a radio frequency (RF) power between about 100 W and about 1500 W, and a voltage bias between about 10 V and about 800 V. Alternatively, the BT etching process may include a selective wet etching process with a hydro fluoride (HF) or NH₄OH etchant. In the illustrated embodiment, after the BT etching process, portions of the low-k spacer layer 164 remain on opposing sidewall surfaces of the gate spacers 128, and the protruding portion of the high-k dielectric layer 152b (if exists) and the recessed gate electrode 154 are exposed again in the recess 160. In some embodiments, a thickness of the remaining portions of the low-k spacer layer 164 ranges from about 0.5 nm to about 1.3 nm. In furtherance of some embodiments, the thickness of the remaining portions of the low-k spacer layer 164 is larger than the thickness of the high-k dielectric layer 152b. The larger thickness of the low-k spacer layer 164 increases a lateral distance between the metal gate structure and the subsequently formed source/drain contact and further reduces parasitic capacitance. In some alternative embodiments, the thickness of remaining portion of the low-k spacer layer 164 is smaller than the thickness of the high-k dielectric layer 152b.

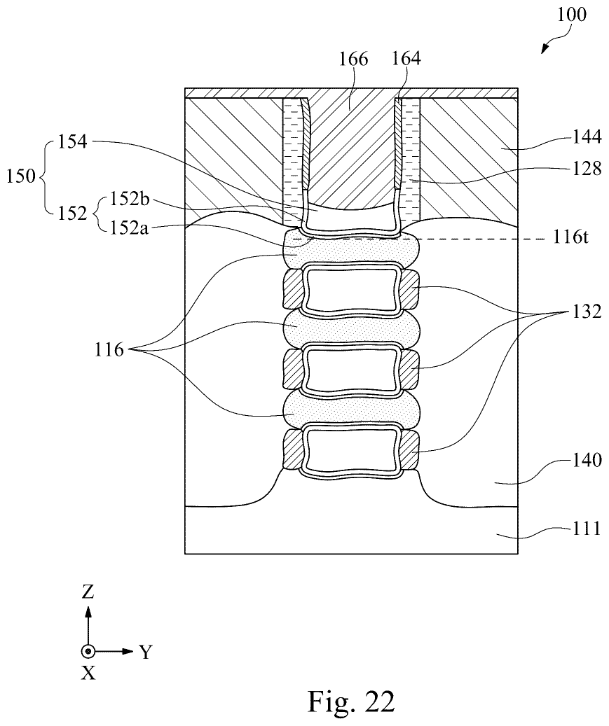

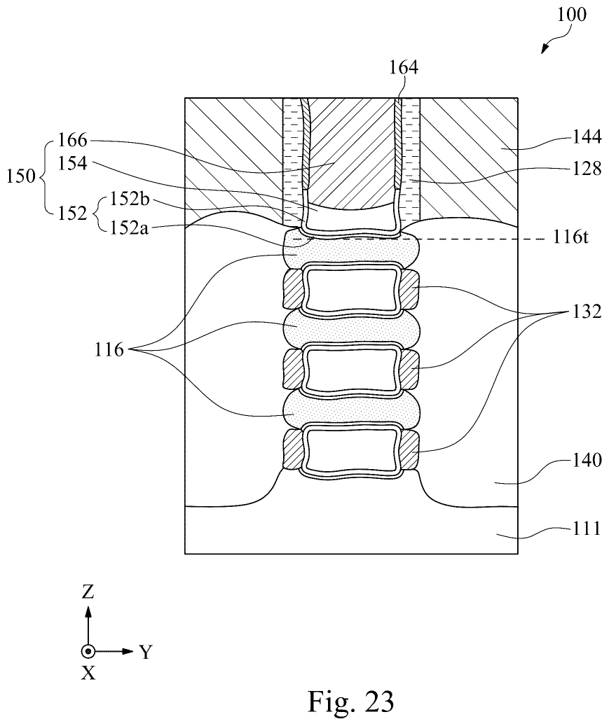

Referring to FIGS. 1 and 22, at operation 48, the method 10 forms a conductive layer 166 filling the recess 160. The conductive layer 166 is made of or includes a metal material. The metal material may include tungsten, ruthenium, aluminum, copper, cobalt, titanium, TiAl, TiAlC, one or more other suitable materials, or a combination thereof. In some embodiments, the conductive layer 166 and the metal filling layer of the recessed gate electrode 154 include different metal materials. For example, the conductive layer 166 may include metal materials with less resistivity compared to the metal filling layer of the recessed gate electrode 154 as an effort to reduce overall resistance of the metal gate structure. In some embodiments, the conductive layer 166 and the metal filling layer of the recessed gate electrode 154 include the same metal material(s). The conductive layer 166 may be deposited over the recessed gate electrode 154 using a CVD process, an ALD process, a PVD process, an electroplating process, an electroless plating process, a spin coating process, one or more other applicable processes, or a combination thereof. The conductive layer 166 may also cover the top surface of the ILD layer 144. The device 100 is then planarized by using, for example, a CMP process, until the top surface of the ILD layer 144 is revealed, such as shown in FIG. 23. In the illustrated embodiment, the conductive layer 166 is in physical contact with the low-k spacer layer 164, the protruding portion of the high-k dielectric layer 152b (if exists) and the recessed gate electrode 154. The recessed gate electrode 154 is also referred to as a first gate electrode 154, and the conductive layer 166 is also referred to as a second gate electrode 166. The gate dielectric layer 152, the first gate electrode 154, and the second gate electrode 166 collectively define the gate stack 150, which is also referred to as the metal gate stack 150 or metal gate structure 150.

As illustrated in cross-sectional view of FIG. 24 that is taken along a longitudinal axis of the gate stack 150, the gate dielectric layer 152 wraps each of the channel members 116, the first gate electrode 154 further wraps the gate dielectric layer 152 and fills the space vertically between adjacent channel members 116, and the second gate electrode 166 is deposited on the top surface of the first gate electrode 154. Notably, during the etching back of the first gate electrode 154, by-products (such as TiCl₄ and/or AlF₃) may remain at the interface between the first gate electrode 154 and the second gate electrode 166 as isolated islands 168 of impurities. Alternatively, the impurities may form a thin film between the first gate electrode 154 and the second gate electrode 166. Similarly, during the etching back of the high-k dielectric layer 152b, by-products (e.g., hafnium-containing by-products, such as HfCl₄ and/or HfFx) may remain at the interface between the high-k dielectric layer 152b and the low-k spacer layer 164 as isolated islands (not shown in FIG. 23) of impurities. Alternatively, the hafnium-containing impurities may form a thin film between the high-k dielectric layer 152b and the low-k spacer layer 164. FIG. 25 is an alternative cross-sectional view taken along a longitudinal axis of the gate stack 150. Many aspects of the device 100 in FIG. 25 are the same as or similar to those in FIG. 24. One difference is that during the etching back of the first gate electrode 154, the recess 160 in the X-Z plane may extend under the channel top surface 116t at corner regions due to etch loading effects. In the embodiment as depicted in FIG. 25, the bottommost portion of the second gate electrode 166 may extend downwardly to a position between the topmost and the middle channel members 116.

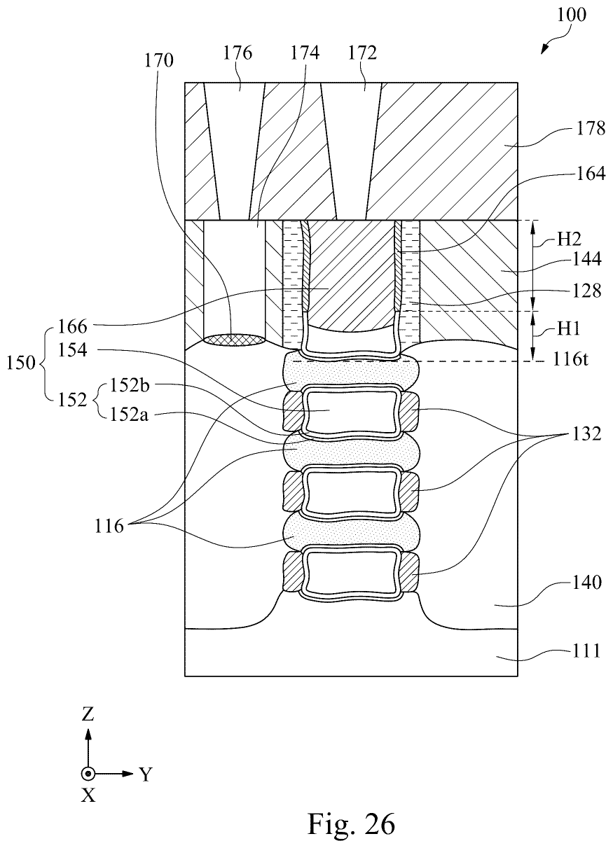

Referring to FIGS. 1 and 26, at operation 50, the method 10 forms gate contact 172, source/drain contact 174, and source/drain contact vias 176. In some embodiments, a first patterned mask (not shown) is formed over the ILD layer 144 with an opening above the source/drain regions 140. An etching process etches the ILD layer 144 through the opening and exposes the source/drain regions 140 in a trench. A silicide feature 170 is formed above the source/drain regions 140 in a silicide formation process. The silicide feature 170 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), a combination thereof, or other suitable compounds. Subsequently, the source/drain contact 174 is formed in the trench and lands on the silicide feature 170 by depositing a conductive material in the trench. The conductive material may include any suitable material, such as W, Co, Ru, Cu, Ta, Ti, Al, Mo, other suitable conductive materials, or combinations thereof, and may be deposited by any suitable method, such as CVD, PVD, ALD, plating, other suitable methods, or combinations thereof. Alternatively, the silicide formation may be skipped and the source/drain contact 174 directly contacts the source/drain feature 140.

After the formation of the source/drain contact 174, an ILD layer 178 is deposited on the ILD layer 144. In some embodiments, the ILD layer 178 includes silicon oxide, silicon silicon nitride, oxynitride, phosphosilicate glass (PSG), borophosphosilicate glass (BPSG), spin-on glass (SOG), fluorinated silica glass (FSG), carbon doped silicon oxide (e.g., SiCOH), polyimide, and/or a combination thereof. In some other embodiments, the ILD layer 178 includes low-k dielectric materials. In some embodiments, the ILD layers 144 and 178 include different dielectric materials. The ILD layer 178 may be formed to a suitable thickness by FCVD, CVD, HDPCVD, SACVD, spin-on, sputtering, or other suitable methods.

After the formation of the ILD layer 178, a second patterned mask (not shown) is formed over the ILD layer 178 with openings above the source/drain contact 174 and the second gate electrode 166, respectively. An etching process etches through the ILD layer 178 through the openings and exposes the source/drain contact 174 and the second gate electrode 166 in the trenches. Subsequently, the source/drain contact via 176 and the gate contact 172 are formed in the trenches and land on the source/drain contact 174 and the second gate electrode 166, respectively, by depositing conductive material in the trenches. The conductive material may include any suitable material, such as W, Co, Ru, Cu, Ta, Ti, Al, Mo, other suitable conductive materials, or combinations thereof, and may be deposited by any suitable method, such as CVD, PVD, ALD, plating, other suitable methods, or combinations thereof. The conductive material in forming the source/drain contact via 176 and the gate contact 172 may be different from the conductive material in forming the source/drain contact 174. Subsequently, a planarization process, such as a CMP process, is performed to remove excessive conductive material and expose the ILD layer 178.

Still referring to FIG. 26, a multi-layer dielectric structure is laterally stacked between the gate stack 150 and the source/drain contact 174. The multi-layer dielectric structure includes the ILD layer 144, the gate spacer 128, the high-k dielectric layer 152b that separates the first gate electrode 154 from contacting the gate spacer 128, and the low-k spacer layer 164 that separates the second gate electrode 166 from contacting the gate spacer 128. In some embodiments, the source/drain contact 174 may be deposited on sidewalls of the gate spacer 128 through a self-aligned formation process, such that the multi-layer dielectric structure does not include the ILD layer 144. In either scenario, a majority portion of the high-k dielectric layer 152b above the channel top surface 116t is replaced by the low-k spacer layer 164. Consequently, the overall dielectric constant of the multi-layer dielectric structure is reduced, which also leads to a reduced parasitic capacitance between the gate stack 150 and the source/drain contact 174. For example, parasitic capacitance may be reduced by about 30% to about 40% by replacing a majority portion of the high-k dielectric layer 152b above the channel top surface 116t with the low-k spacer layer 164. In some embodiments, a ratio of the height H1 of the high-k dielectric layer 152b measured above the channel top surface 116t and the height H2 of the low-k spacer layer 164 (H1/H2) is in a range from about 1:20 to about 1:2. This range is not arbitrary. If H1/H2 is less than 1:20, the gate stack 150 may have an aspect ratio that is too large that increases manufacturing difficulties; if H1/H2 is larger than 1:2, the parasitic capacitance may not be effectively reduced due to the large portion of the high-k dielectric layer 152b remaining laterally between the gate stack 150 and the source/drain contact 174.

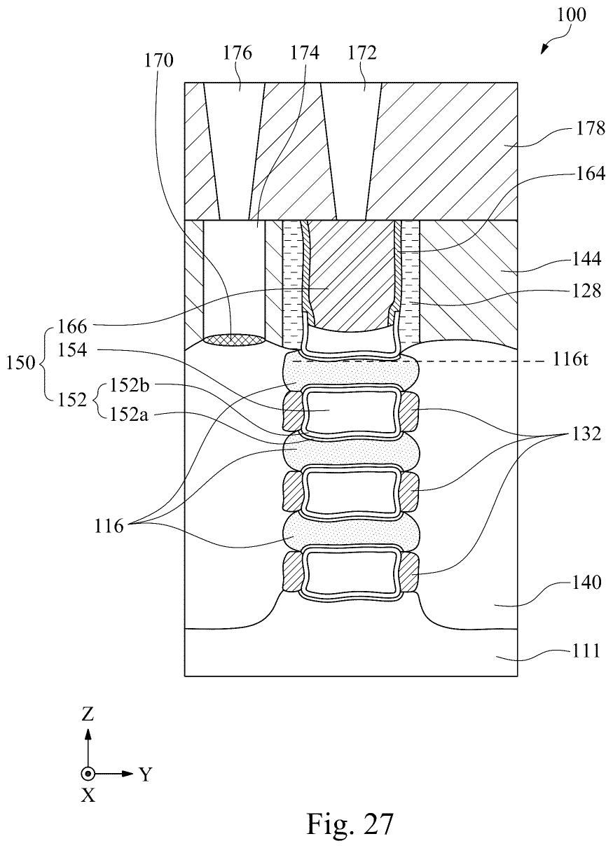

FIG. 27 illustrates an alternative embodiment of the device 100. Many aspects of the device 100 in FIG. 27 are the same as or similar to those in FIG. 26. One difference is that in FIG. 27, the low-k spacer layer 164 covers the protruding portion of the high-k dielectric layer 152b due to the larger thickness of the low-k spacer layer 164. In this alterative embodiment, the bottom surface of the low-k spacer layer 164 is in physical contact with the first gate electrode 154 and separates the high-k dielectric layer 152b from contacting the second gate electrode 166.

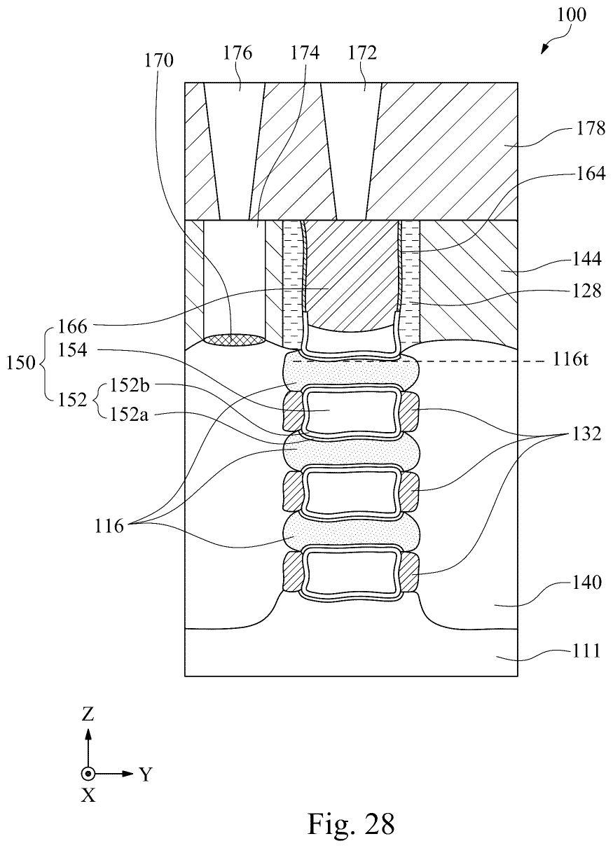

FIG. 28 illustrates another alternative embodiment of the device 100. Many aspects of the device 100 in FIG. 28 are the same as or similar to those in FIG. 26. One difference is that in FIG. 28, the low-k spacer layer 164 is thinner than the high-k dielectric layer 152b, such that the top surface of the high-k dielectric layer 152b is not fully covered by the low-k spacer layer 164 and in physical contact with the second gate electrode 166.

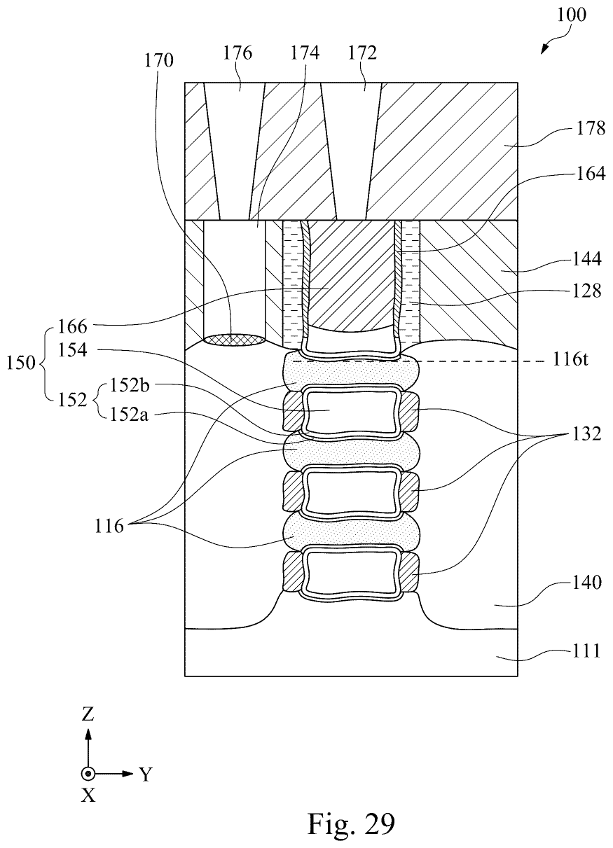

FIG. 29 illustrates yet another alternative embodiment of the device 100. Many aspects of the device 100 in FIG. 29 are the same as or similar to those in FIG. 26. One difference is that in FIG. 29, the high-k dielectric layer 152b is recessed below the recessed gate electrode 154 (also as shown in the alternative corner region 162′ of FIG. 19), and the bottom portion of the low-k spacer layer 164 protrudes downwardly to a position laterally between the first gate electrode 154 and the gate spacer 128. The high-k dielectric layer 152b is also free of contact from the second gate electrode 166.

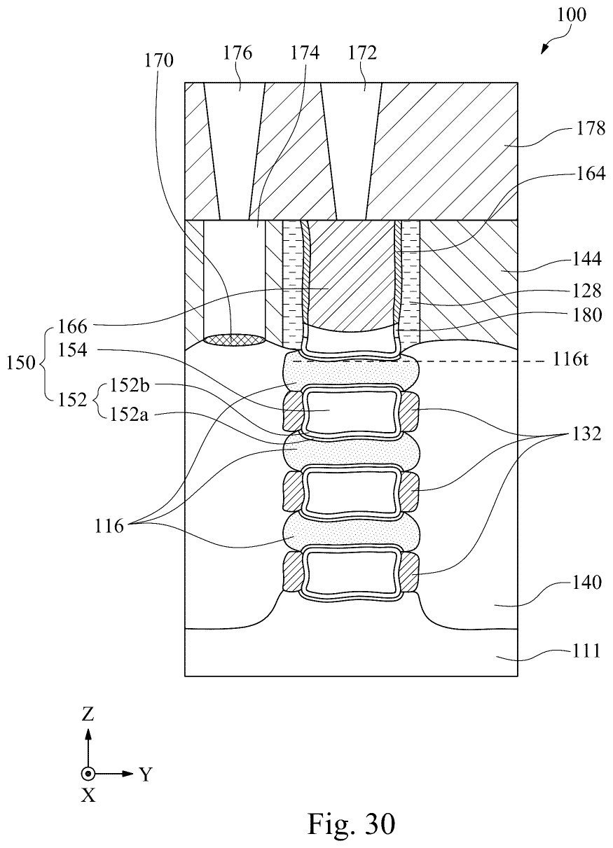

FIG. 30 illustrates yet another alternative embodiment of the device 100. Many aspects of the device 100 in FIG. 30 are the same as or similar to those in FIG. 26. One difference is that in FIG. 30, the high-k dielectric layer 152b is recessed below the recessed gate electrode 154 (also as shown in the alternative corner region 162′ of FIG. 19), and voids 180 (or referred to as air gap) are sealed by the bottom portion of the low-k spacer layer 164. The high-k dielectric layer 152b is free of contact from the second gate electrode 166. The voids 180 are formed due to the limited gap filling capability of the low-k spacer layer 164 during the deposition of the low-k spacer layer 164 into the gaps between the recessed high-k dielectric layer 152b and the recessed gate electrode 154. The voids 180 may be positioned above the top surfaces of the source/drain regions 140. The voids 180 further reduce the overall dielectric constant of the multi-layer dielectric structure between the gate stack 150 and the source/drain contact 174, which leads to smaller parasitic capacitance.

Although not intended to be limiting, one or more embodiments of the present disclosure provide many benefits to a semiconductor device and the formation thereof. For example, embodiments of the present disclosure provide a multi-layer dielectric structure stacked between a gate electrode of a metal gate structure and a source/drain contact, which effectively reduces parasitic capacitance of the structure by including a low-k dielectric layer disposed on a recessed high-k dielectric layer. Furthermore, the forming of the blocking layer can be easily integrated into existing semiconductor fabrication processes.

In one exemplary aspect, the present disclosure is directed to a method of manufacturing a semiconductor device. The method includes alternately stacking first semiconductor layers and second semiconductor layers over a substrate, patterning the first and second semiconductor layers into a fin structure, forming a dummy gate structure across the fin structure, depositing gate spacers over sidewalls of the dummy gate structure, laterally recessing end portions of the first semiconductor layers, forming inner spacers on end portions of the first semiconductor layers, removing the dummy gate structure to form a recess, the recess exposing sidewalls of the gate spacers, removing the first semiconductor layers thereby forming gaps between the second semiconductor layers, depositing an interfacial layer wrapping around each of the second semiconductor layers, depositing a high-k dielectric layer over the interfacial layer and over the sidewalls of the gate spacers, depositing a first gate electrode over the high-k dielectric layer, recessing the first gate electrode, recessing the high-k dielectric layer to expose a top portion of the sidewalls of the gate spacers, depositing a low-k dielectric layer over the recessed high-k dielectric layer and over the exposed top portion of the sidewalls of the gate spacers, and depositing a second gate electrode over the first gate electrode. In some embodiments, the method also includes forming an epitaxial feature abutting end portions of the second semiconductor layers, and forming a contact over and in electrical coupling with the epitaxial feature, the low-k dielectric layer being laterally stacked between the contact and the second gate electrode. In some embodiments, a topmost portion of the high-k dielectric layer is above a top surface of the recessed first gate electrode. In some embodiments, the topmost portion of the high-k dielectric layer is above the top surface of the recessed first gate electrode for a vertical distance less than about 2 nm. In some embodiments, a topmost portion of the high-k dielectric layer is below a top surface of the recessed first gate electrode. In some embodiments, the topmost portion of the high-k dielectric layer is below the top surface of the recessed first gate electrode for a vertical distance less than about 2 nm. In some embodiments, the low-k dielectric layer is thicker than the high-k dielectric layer. In some embodiments, an interface between the low-k dielectric layer and the high-k dielectric layer includes hafnium-containing impurities. In some embodiments, an interface between the first gate electrode and the second gate electrode includes titanium-containing or aluminum-containing impurities. In some embodiments, the low-k dielectric layer has a dielectric constant value less than the gate spacers.

In another exemplary aspect, the present disclosure is directed to a method. The method includes forming vertically stacked channel members suspended above a substrate, forming an epitaxial material abutting opposing ends of the channel members, depositing a gate dielectric layer wrapping around the channel members, depositing a first gate electrode over the gate dielectric layer, recessing the first gate electrode and the gate dielectric layer, forming a spacer layer over the gate dielectric layer, a dielectric constant of the spacer layer being less than a dielectric constant of the gate dielectric layer, depositing a second gate electrode over the first gate electrode, wherein the spacer layer is disposed on sidewalls of the second gate electrode, and forming a contact over the epitaxial material, the spacer layer being laterally stacked between the contact and the second gate electrode. In some embodiments, the forming of the spacer layer includes conformally depositing a dielectric layer over the gate dielectric layer and the first gate electrode, and removing horizontal portions of the dielectric layer to expose the first gate electrode, vertical portions of the dielectric layer remaining as the spacer layer. In some embodiments, the method also includes forming gate spacers over the epitaxial material, the gate spacers being in physical contact with the spacer layer. In some embodiments, the gate spacers are in physical contact with the gate dielectric layer. In some embodiments, a bottom surface of the second gate electrode is below a bottom surface of the spacer layer. In some embodiments, the dielectric constant of the spacer layer is less than about 2.5. In some embodiments, the spacer layer separates the gate dielectric layer from physically contacting the second gate electrode.

In yet another exemplary aspect, the present disclosure is directed to a semiconductor device. The semiconductor device includes semiconductor channel members vertically stacked over a substrate, a gate stack. The gate stack includes a high-k dielectric layer wrapping around the semiconductor channel members, a first gate electrode over the high-k dielectric layer, a second gate electrode over the first gate electrode, and a low-k dielectric layer disposed on sidewalls of the second gate electrode and over the high-k dielectric layer. The semiconductor device also includes gate spacers disposed on sidewalls of the gate stack, a source/drain feature abutting the semiconductor channel members, and a source/drain contact disposed on the source/drain feature. The low-k dielectric layer is laterally stacked between the source/drain contact and the second gate electrode. In some embodiments, the gate spacers are in physical contact with the high-k dielectric layer and the low-k dielectric layer. In some embodiments, a bottom surface of the second gate electrode is below a top surface of a topmost one of the semiconductor channel members.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a fin-shaped base protruding from a substrate;
an isolation feature disposed on sidewalls of the fin-shaped base;
a plurality of nanostructures vertically stacked over the fin-shaped base;
a gate structure, wherein the gate structure includes a gate dielectric layer wrapping around the nanostructures, a first gate electrode disposed on the gate dielectric layer, a second gate electrode disposed on the first gate electrode, and a dielectric spacer disposed on a sidewall of the second gate electrode; and
a gate spacer extending along a sidewall of the gate structure,
wherein a dielectric constant of the gate dielectric layer is greater than a dielectric constant of the gate spacer, and the dielectric constant of the gate dielectric layer is greater than a dielectric constant of the dielectric spacer.

2. The semiconductor device of claim 1, wherein the dielectric spacer is laterally stacked between the gate spacer and the second gate electrode.

3. The semiconductor device of claim 1, wherein the dielectric spacer is formed of a porous dielectric material.

4. The semiconductor device of claim 1, wherein the dielectric constant of the dielectric spacer is less than about 2.5.

5. The semiconductor device of claim 1, wherein a thickness of the dielectric spacer is greater than a thickness of the gate dielectric layer.

6. The semiconductor device of claim 1, wherein a thickness of the dielectric spacer is smaller than a thickness of the gate dielectric layer.

7. The semiconductor device of claim 1, wherein the first gate electrode and the second gate electrode include different material compositions.

8. The semiconductor device of claim 1, wherein a conductivity of the second gate electrode is less than a conductivity of the first gate electrode.

9. The semiconductor device of claim 1, wherein the first gate electrode and the second gate electrode include a same material composition but with a discernable interface between the first gate electrode and the second gate electrode.

10. The semiconductor device of claim 1, wherein top surfaces of the gate spacer, the dielectric spacer, and the second gate electrode are coplanar.

11. A semiconductor device, comprising:
a plurality of nanostructures vertically stacked over a substrate;
a gate stack, wherein the gate stack includes a high-k dielectric layer wrapping around the nanostructures, a gate electrode disposed over the high-k dielectric layer, and a low-k dielectric layer disposed over the high-k dielectric layer;
gate spacers disposed on sidewalls of the gate stack and interfacing with the low-k dielectric layer, wherein a dielectric constant of the high-k dielectric layer is greater than a dielectric constant of the gate spacers;
a source/drain feature abutting the nanostructures; and
a source/drain contact disposed on the source/drain feature, wherein the low-k dielectric layer is laterally stacked between the source/drain contact and the gate electrode.

12. The semiconductor device of claim 11, wherein the gate electrode includes a first gate electrode layer wrapping around the nanostructures and a second gate electrode layer disposed over the first gate electrode layer.

13. The semiconductor device of claim 12, wherein the low-k dielectric layer interfaces with both the first and second gate electrode layers.

14. The semiconductor device of claim 12, wherein the low dielectric layer interfaces with the second gate electrode layer and is spaced apart from the first gate electrode layer.

15. The semiconductor device of claim 11, wherein a height of the low-k dielectric layer is greater than a height of the high-k dielectric layer.

16. A method of manufacturing a semiconductor device, comprising:
alternately stacking first semiconductor layers and second semiconductor layers over a substrate;
patterning the first and second semiconductor layers into a fin structure;
forming a dummy gate structure across the fin structure;
depositing gate spacers over sidewalls of the dummy gate structure;
recessing the fin structure in a region adjacent to the gate spacers to form a source/drain recess;
forming a source/drain epitaxial feature in the source/drain recess, the source/drain epitaxial feature abutting the second semiconductor layers;
removing the dummy gate structure to form a gate trench, the gate trench exposing sidewalls of the gate spacers;
removing the first semiconductor layers thereby forming gaps between the second semiconductor layers;
depositing a gate dielectric layer wrapping around the second semiconductor layers;
depositing a first gate electrode over the gate dielectric layer;
recessing the first gate electrode to expose the gate dielectric layer;
recessing the gate dielectric layer to expose a top portion of the sidewalls of the gate spacers;
depositing a dielectric spacer over the recessed gate dielectric layer and over the exposed top portion of the sidewalls of the gate spacers; and
depositing a second gate electrode over the first gate electrode and interfacing with the dielectric spacer.

17. The method of claim 16, further comprising:
forming a contact over and in electrical coupling with the source/drain epitaxial feature, wherein the dielectric spacer is laterally stacked between the contact and the second gate electrode.

18. The method of claim 16, wherein the dielectric spacer is thicker than the gate dielectric layer.

19. The method of claim 16, wherein the dielectric spacer is thinner than the gate dielectric layer.

20. The method of claim 16, wherein an interface between the dielectric spacer and the gate dielectric layer includes hafnium-containing impurities.
